(19) United States
(12) Patent Application Publication
(10) Pub. No.: US 2025/0127008 A1
(43) Pub. Date: Apr. 17, 2025

(54) Display Panel and Display Apparatus

(71) Applicant: BOE TECHNOLOGY GROUP CO., LTD., Chaoyang District, Beijing (CN)

(72) Inventors: Xiaojin Zhang, Beijing (CN); Haiyan Sun, Beijing (CN)

(21) Appl. No.: 18/294,613

(22) PCT Filed: May 19, 2023
(86) PCT No.: PCT/CN2023/095244

§ 371 Date: Feb. 2, 2024

(51) Int. Cl. H10K 59/50; G02F 1/1335; H10K 59/122; H10K 59/126; H10K 59/80

(52) U.S. Cl. CPC H10K 59/50; G02F 1/133543; H10K 59/122; H10K 59/126; H10K 59/8731; H10K 59/8791

(57) ABSTRACT

A display panel includes a backplane and a plurality of light-emitting devices located on the backplane. A light-emitting device includes a first electrode and a second electrode arranged oppositely, the first electrode being closer to the backplane than the second electrode; a light extraction layer located on a light exit side of the plurality of light-emitting devices, the light extraction layer being configured to allow circularly polarized light of a first rotation direction to pass through and reflect circularly polarized light of a second rotation, the first rotation direction being different from the second rotation direction; and an anti-reflection layer located on the light extraction layer, the anti-reflection layer being configured to allow the circularly polarized light of the first rotation direction to pass through.

### CROSS-REFERENCE TO RELATED APPLICATION

This application is the United States national phase of International Patent Application No. PCT/CN2023/095244 filed May 19, 2023, the disclosure of which is hereby incorporated by reference in its entirety.

### BACKGROUND OF THE INVENTION

### Field of the Invention

The present disclosure relates to the field of display technologies, and in particular, to a display panel and a display apparatus.

### Description of Related Art

Organic light-emitting diode (OLED) display apparatuses have advantages such as thinness, lightness, wide viewing angle, active light-emitting, continuously adjustable light-emitting color, low cost, fast response speed, low energy consumption, low driving voltage, wide operating temperature range, simple manufacturing process, high luminous efficiency, and flexible display, and have been listed as a next-generation display technology with great development prospects.

### SUMMARY OF THE INVENTION

In an aspect, a display panel is provided. The display panel includes a backplane, a plurality of light-emitting devices, a light extraction layer and an anti-reflection layer. The plurality of light-emitting devices are located on the backplane. A light-emitting device includes a first electrode and a second electrode arranged oppositely, and the first electrode is closer to the backplane than the second electrode. The light extraction layer is located on a light exit side of the plurality of light emitting devices. The light extraction layer is configured to allow circularly polarized light of a first rotation direction to pass through and reflect circularly polarized light of a second rotation direction; the first rotation direction is different from the second rotation direction. The anti-reflection layer is located on the light extraction layer; the anti-reflection layer is configured to allow the circularly polarized light of the first rotation direction to pass through.

In some embodiments, a transmittance of the light extraction layer to light emitted by the light-emitting device is greater than or equal to 35%, and/or a reflectivity of the light extraction layer to the light emitted by the light-emitting device is greater than or equal to 35%.

In some embodiments, a material of the extraction layer includes at least one type of cholesteric liquid crystals; in a case where the material of the light extraction layer includes at least two types of cholesteric liquid crystals, helical pitches of the at least two types of cholesteric liquid crystals are not equal.

In some embodiments, in the case where the material of the light extraction layer includes at least two types of cholesteric liquid crystals, the light extraction layer includes at least two light extraction sub-layers stacked in sequence; the at least two light extraction sub-layers include a first light extraction layer and a second light extraction layer, and a helical pitch of cholesteric liquid crystals in the first light extraction layer and a helical pitch of cholesteric liquid crystals in the second light extraction layer are not equal.

In some embodiments, in the case where the material of the light extraction layer includes at least two types of cholesteric liquid crystals, the at least two types of cholesteric liquid crystals include first liquid crystals and second liquid crystals; the first liquid crystals are evenly distributed in the light extraction layer, the second liquid crystals are evenly distributed in the light extraction layer, and a distribution density of the first liquid crystals in the light extraction layer is substantially equal to a distribution density of the second liquid crystals in the light extraction layer.

In some embodiments, in the case where the material of the light extraction layer includes at least two types of cholesteric liquid crystals, in the light extraction layer, helical pitches of cholesteric liquid crystals corresponding to light-emitting devices with different light-emitting colors are not equal.

In some embodiments, the anti-reflection layer includes at least a ¼ wave plate and a polarizing layer; the ¼ wave plate is located between the polarizing layer and the light extraction layer; a transmittance of the polarizing layer to visible light is greater than or equal to 40%.

In some embodiments, the anti-reflection layer further includes a light absorption layer; the light absorption layer is stacked on the ¼ wave plate or the polarizing layer, and is used to absorb light with a wavelength in a range below 450 nm.

In some embodiments, the display panel further includes a definition layer located between the backplane and the light extraction layer, and the definition layer has a plurality of second openings. The plurality of light-emitting devices include red light-emitting devices, a green light-emitting devices and blue light-emitting devices. The plurality of second openings include red openings for arranging the red light-emitting devices, green openings for arranging the green light-emitting devices, and blue openings for arranging the blue light-emitting devices. An area of an orthographic projection of a red opening on the backplane is less than or equal to an area of an orthogonal projection of a green opening on the backplane.

In some embodiments, a ratio of an area of an orthographic projection of a blue opening on the backplane to the area of the orthographic projection of the red opening on the backplane is γ, where 1.0≤y≤2.6.

In some embodiments, a sum of areas of orthographic projections of all the blue openings in a display region of the display panel on the backplane is less than or equal to 10% of an area of the display region of the display panel.

In some embodiments, a ratio of a sum of areas of orthographic projections of all the second openings in a display region of the display panel on the backplane to an area of the display region is in a range of 10% to 70%, inclusive.

In some embodiments, an included angle between a side wall of a second opening and a plane where the backplane is located is less than or equal to 35°.

In some embodiments, the display panel further includes a light shielding layer disposed between a plurality of light-emitting devices and the light extraction layer; the light shielding layer has a plurality of first openings; an orthographic projection of the light-emitting device on the backplane and an orthogonal projection of a first opening on the backplane have an overlapping region therebetween.

In some embodiments, the display panel has a first region and a second region; an included angle between a side wall of at least one first opening in the first region and a plane where the backplane is located is not equal to an included angle between a side wall of at least one first opening in the second region and the plane where the backplane is located.

In some embodiments, the display panel further includes a definition layer located between the backplane and the light shielding layer, and the definition layer has a plurality of second openings; a second opening is arranged directly opposite to a first opening in a direction perpendicular to a plane where the backplane is located.

In some embodiments, the display panel has a third region and a fourth region. An included angle between a side wall of at least one second opening in the third region and the plane where the backplane is located is not equal to an included angle between a side wall of at least one second opening in the fourth region and the plane where the backplane is located.

In some embodiments, an orthographic projection of the second opening on the backplane is within an orthographic projection of the first opening directly opposite to the second opening on the backplane.

In some embodiments, an included angle between a side wall of the first opening and the plane where the backplane is located is greater than an included angle between a side wall of the second opening and the plane where the backplane is located.

In some embodiments, an included angle between a side wall of the first opening and the plane where the backplane is located is less than an included angle between a side wall of the second opening and the plane where the backplane is located.

In some embodiments, a material of the definition layer includes a light absorbing material, and/or a material of the light shielding layer includes a light absorbing material; absorbance of the light shielding material is greater than or equal to 0.5.

In some embodiments, a maximum distance between a border line of an orthographic projection of the second opening on the backplane and a border line of the orthographic projection of the first opening directly opposite to the second opening on the backplane is less than or equal to ⅓ of a maximum size of the orthographic projection of the second opening on the backplane.

In some embodiments, the display panel further includes: an optical covering layer located between the plurality of light emitting devices and the light extraction layer, and an encapsulation layer located between the optical covering layer and the light extraction layer and in contact with the optical covering layer; a difference between refractive index of the optical covering layer and refractive index of the encapsulation layer is greater than or equal to 0.1.

In some embodiments, the encapsulation layer includes at least three encapsulation sub-layers; refractive indexes of at least two encapsulation sub-layers of the at least three encapsulation sub-layers are greater than or equal to 1.65.

In some embodiments, the at least three encapsulation sub-layers include a first encapsulation sub-layer, a second encapsulation sub-layer and a third encapsulation sub-layer; the first encapsulation sub-layer is in contact with the optical covering layer; a material of the first encapsulation sub-layer is an inorganic material, a material of the second encapsulation sub-layer is an organic material, and a material of the third encapsulation sub-layer is an inorganic material; the first encapsulation sub-layer includes a fourth encapsulation sub-layer and a fifth encapsulation sub-layer that are stacked.

In some embodiments, a refractive index of the fourth encapsulation sub-layer is less than a refractive index of the fifth encapsulation sub-layer.

In some embodiments, the display panel further includes a touch function layer located between the encapsulation layer and the light extraction layer.

In another aspect, a display apparatus is provided. The display apparatus includes the display panel as described in any one of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to those drawings. In addition, the accompanying drawings to be described below may be regarded as schematic diagrams, and are not limitations on actual sizes of products involved in the embodiments of the present disclosure.

FIG. 1 is a schematic diagram of a display apparatus, in accordance with some embodiments of the present disclosure;

FIG. 2A is a structural diagram of a display panel, in accordance with an implementation;

FIG. 2B is a schematic diagram of a changing process of light emitted by a light-emitting device in a display panel incident on an anti-reflective structure, in accordance with an implementation;

FIG. 3 is a structural diagram of a display panel, in accordance with some embodiments of the present disclosure;

FIG. 4 is a schematic diagram of a changing process of light emitted by a light-emitting device in a display panel incident on a light extraction layer and anti-reflection layer, in accordance with some embodiments of the present disclosure;

FIG. 5 is a schematic diagram of tested reflectivity of a light extraction layer, in accordance with some embodiments of the present disclosure;

FIG. 6 is a diagram of relationship of reflectivity of a light extraction layer and a wavelength of incident light, in accordance with some embodiments of the present disclosure;

FIG. 7A is a structural diagram of another display panel, in accordance with some embodiments of the present disclosure;

FIG. 7B is a structural diagram of another display panel, in accordance with some embodiments of the present disclosure;

FIG. 7C is a structural diagram of another display panel, in accordance with some embodiments of the present disclosure;

FIG. 7D is a structural diagram of another display panel, in accordance with some embodiments of the present disclosure;

FIG. 8 is a structural diagram of yet another display panel, in accordance with some embodiments of the present disclosure;

FIG. 9A is a structural diagram of yet another display panel, in accordance with some embodiments of the present disclosure;

FIG. 9B is a structural diagram of yet another display panel, in accordance with some embodiments of the present disclosure;

FIG. 10A is a structural diagram of yet another display panel, in accordance with some embodiments of the present disclosure;

FIG. 10B is a structural diagram of yet another display panel, in accordance with some embodiments of the present disclosure;

FIG. 11 is a structural diagram of a light shielding layer and a definition layer, in accordance with some embodiments of the present disclosure;

FIG. 12 is a structural diagram of yet another display panel, in accordance with some embodiments of the present disclosure;

FIG. 13 is a structural diagram of a definition layer and a light-emitting device, in accordance with some embodiments of the present disclosure;

FIG. 14 is a structural diagram of yet another display panel, in accordance with some embodiments of the present disclosure;

FIG. 15A is a structural diagram of an encapsulation layer, in accordance with some embodiments of the present disclosure;

FIG. 15B is a structural diagram of another encapsulation layer, in accordance with some embodiments of the present disclosure; and

FIG. 16 is a structural diagram of yet another display panel, in accordance with some embodiments of the present disclosure.

### DESCRIPTION OF THE INVENTION

The technical solutions in some embodiments of the present disclosure will be described clearly and completely with reference to the accompanying drawings; obviously, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example”, or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

The terms “first” and “second” are used for descriptive purposes only, and are not to be construed as indicating or implying a relative importance or implicitly indicating a number of indicated technical features. Thus, a feature defined with “first” or “second” may explicitly or implicitly include one or more of the features. In the description of the embodiments of the present disclosure, the term “a plurality of” or “the plurality of” means two or more unless otherwise specified.

The phrase “A and/or B” includes the following three combinations: only A, only B, and a combination of A and B.

The use of the phrase “applicable to” or “configured to” herein means an open and inclusive expression, which does not exclude devices that are applicable to or configured to perform additional tasks or steps.

The term such as “about”, “substantially”, and “approximately” as used herein includes a stated value and an average value within an acceptable range of deviation of a particular value. The acceptable range of deviation is determined by a person of ordinary skill in the art, considering measurement in question and errors associated with measurement of a particular quantity (i.e., limitations of a measurement system).

The term such as “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be a difference between two equals being less than or equal to 5% of either of the two equals.

It will be understood that, in a case where a layer or an element is referred to as being on another layer or a substrate, it may be that the layer or the element is directly on the another layer or the substrate, or there may be a middle layer between the layer or the element and the another layer or the substrate.

Exemplary embodiments are described herein with reference to sectional views and/or plan views as idealized exemplary drawings. In the accompanying drawings, thicknesses of layers and areas of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a curved feature. Therefore, the regions shown in the accompanying drawings are schematic in nature, and their shapes are not intended to show actual shapes of the regions in a device, and are not intended to limit the scope of the exemplary embodiments.

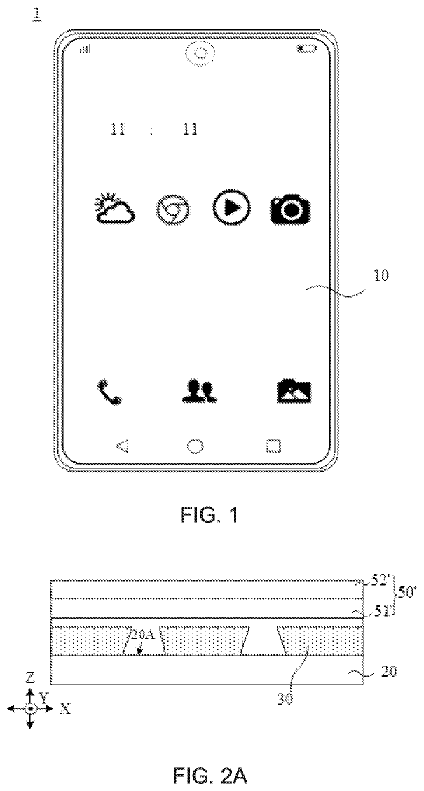

As shown in FIG. 1, some embodiments of the present disclosure provide a display apparatus 1. The display apparatus 1 may be any display device that displays images whether in motion (e.g., a video) or stationary (e.g., a still image), and regardless of text or image. More specifically, it is expected that the display apparatus provided by the embodiments may be implemented in or associated with a plurality of electronic devices. The plurality of electronic devices may include (but is not limit to), for example, mobile telephones, wireless devices, personal data assistants (PAD), hand-held or portable computers, GPS receivers/navigators, cameras, MP4 video players, video cameras, game consoles, watches, clocks, calculators, TV monitors, flat panel displays, computer monitors, car displays (such as odometer displays, etc.), navigators, cockpit controllers and/or displays, camera view displays (such as rear view camera displays in vehicles), electronic photos, electronic billboards or indicators, projectors, building structures, packagings and aesthetic structures (such as a display for an image of a piece of jewelry).

In some embodiments, as shown in FIG. 1, the display apparatus 1 includes a display panel 10. The display panel 10 has a display region.

For example, the display panel 10 may be an organic light-emitting diode (OLED) display panel or a quantum dot light-emitting diode (QLED) display panel.

The following description will be made by taking an example in which the display panel 10 is an OLED display panel.

For example, the display apparatus 1 further includes a frame, a display driving integrated circuit (IC) and other electronic components.

For example, the display panel 10 is located in the frame, and the frame may play a certain role in supporting the display panel 10 and protecting it from external bumps and other damage. The display panel 10 is electrically connected to the display driving IC for receiving display signals transmitted by the display driving IC and displaying images under the control of the display signals.

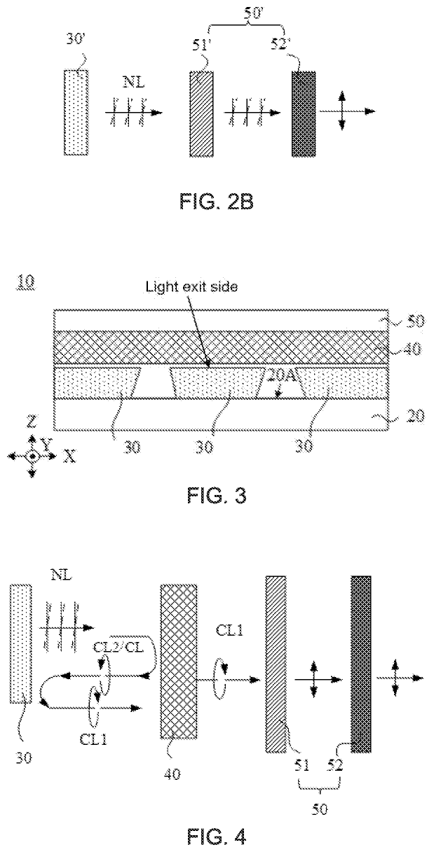

For example, as shown in FIG. 2A, the display panel 10 includes a backplane 20 and a plurality of light-emitting devices 30 disposed on the backplane 20. The plurality of light-emitting devices 30 is located in the display region.

In FIG. 2A, X represents a first direction, Y represents a second direction, and Z represents a third direction. The first direction X and the second direction Y are both parallel to a plane where the backplane 20 is located, and the first direction X and the second direction Y are perpendicular to each other. The third direction Z is a direction perpendicular to the plane where the backplane 20 is located or a thickness direction of the backplane 20.

For example, the backplane 20 has a first surface 20A, and the plurality of light-emitting devices 30 are located on the first surface 20A. The plurality of light-emitting devices 30 may be directly contact with (for example, there is no other film layers provided between the light-emitting devices 30 and the first surface 20A) or may not be contact with (for example, there is a film layer separating the light-emitting devices 30 and the first surface 20A between the two) the first surface 20A.

For example, the backplane 20 includes a plurality of pixel circuits, and the plurality of pixel circuits may be electrically connected to the plurality of light-emitting devices 30 in a one-to-one correspondence. The light-emitting device 30 may emit light under the control of a control signal transmitted from the pixel circuit.

The structure of the pixel circuit varies, which may be set according to actual needs. For example, the pixel circuit may include a structure such as “6T1C,” “7T1C,” “6T2C,” or “7T2C”. Here, “T” represents a thin film transistor, and the number before “T” represents the number of thin film transistors, “C” represents a storage capacitor, and the number before “C” represents the number of storage capacitors.

For example, the light-emitting devices 30 may be OLED light-emitting devices. For example, the light-emitting devices 30 may emit natural light NL.

Natural light vibrates evenly in all different directions. The light-emitting device 30 may emit light in different wavelength bands, such as red light, blue light, or green light. The red light, blue light, and green light are all natural light.

For example, the light-emitting device 30 includes: a first electrode and a second electrode arranged oppositely, and a light-emitting layer located between the first electrode and the second electrode. The first electrode is closer to the backplane 20 than the second electrode.

For example, the light-emitting layer emits light due to the action of an electric field provided by the first electrode and the second electrode. For example, the first electrode is located on the first surface of the backplane 20, and the second electrode is located on a side of the first electrode 31 away from the backplane 20. For example, the first electrode may be one of an anode and a cathode, and the second electrode may be the other of the anode and the cathode, which is not limited in the present disclosure. For example, the first electrode is an anode, and the second electrode is a cathode. It will be understood that, the display panel 10 includes a plurality of conductive layers, such as a pixel conductive layer used to form pixel circuits and a conductive layer used to form the first electrode of a light-emitting device. In a case where an external environment where the display panel is located is relatively bright (which may also be said that in a bright viewing field), the light from the external environment will enter the interior of the display panel, and will be reflected on the plurality of conductive layers and then emits from a light exit side of the display panel, resulting in a great reduction in the contrast of the display panel and affecting the display effect of the display panel.

Therefore, in an implementation, as shown in FIG. 2A, an anti-reflection structure 50′ is provided on the light exit side of the plurality of light-emitting devices 30. The anti-reflective structure 50′ may reduce the reflectivity of the display panel to external light and improve the contrast of the display panel in the bright viewing field. The anti-reflection structure 50′ generally includes a phase conversion structure 51′ and a linear polarizer 52′. The linear polarizer 52′ may transmit light parallel to a direction of the transmission axis of the linear polarizer 52′. Specifically, reference may be made to the schematic diagram of the changing process of light shown in FIG. 2B. However, the light emitted by the light-emitting device 30 will enter the linear polarizer 52′ of the anti-reflection structure 50′, and at least 50% of the light is absorbed and consumed by the anti-reflection structure 50′ (this part of the light is not shown in FIG. 2B), the remaining light may emit through the anti-reflective structure 50′, so that the brightness of the image displayed on the display panel is reduced sharply, the power consumption of the display panel and the display apparatus is increased, and the display life is reduced.

In order to solve these technical problems, some embodiments of the present disclosure provide a display panel; as shown in FIG. 3, the display panel 10 includes a backplane 20, a plurality of light-emitting devices 30 disposed on the backplane 20, a light extraction layer 40 and an anti-reflective layer 50. For the structures of the backplane 20 and the light-emitting device 30, reference may be made to the description of the above embodiments.

FIG. 4 is a simple schematic diagram of a changing process of light, sequentially passing through the light extraction layer 40 and the anti-reflection layer 50, emitted by the light-emitting device in the display panel provided by the embodiments of the present disclosure.

In some examples, the light extraction layer 40 is located on the light exit side of the plurality of light emitting devices 30. The light extraction layer 40 is configured to allow circularly polarized light CL1 of a first rotation direction to pass through and to reflect circularly polarized light CL2 of a second rotation direction; the first rotation direction is different from the second rotation direction. The anti-reflection layer 50 is configured to allow the circularly polarized light CL1 of the first rotation direction to pass through.

For example, the light extraction layer 40 has a modulating effect on the light incident thereon, and is capable of modulating the natural light NL or the light emitted by the light-emitting device 30 into the circularly polarized light CL.

A polarization characteristic test is performed on the light emitted from the light extraction layer 40. For example, a ¼ wave plate, a polarizer, and a receiver are sequentially provided on a side of the light extraction layer 40, the light is incident from a side of the light extraction layer away from the ¼ wave plate, and the polarizer is rotated with the light path as an axis, and a cross-polarization extinction test is performed. It can be found that under different rotation directions of the polarizer, the brightness of the light received by the receiver is different; in the light received by the receiver, a ratio of a brightness value of light with the maximum brightness to a brightness value of light with the minimum brightness is greater than 5. That is, the light transmitted through the light extraction layer 40 has a circular polarization characteristic. For example, the light extraction layer 40 further has a screening effect on light. The light extraction layer 40 has a rotation direction, and is capable of transmitting the light whose rotation direction is opposite to the rotation direction of the light extraction layer 40 and reflecting the light whose rotation direction is the same as the rotation direction of the light extraction layer 40.

For example, the circularly polarized light CL includes circularly polarized light CL1 of a first rotation direction and circularly polarized light CL2 of a second rotation direction.

The first rotation direction may be opposite to the second rotation direction. For example, the first rotation direction may be clockwise, so the circularly polarized light CL1 of the first rotation direction is right-handed circularly polarized light; the second rotation direction may be anticlockwise, so the circularly polarized light CL2 of the second rotation direction is left-handed circularly polarized light.

For another example, the first rotation direction may be anticlockwise, so the circularly polarized light CL1 of the first rotation direction is left-handed circularly polarized light; the second rotation direction may be clockwise, so the circularly polarized light CL2 of the second rotation direction is right-handed circularly polarized light.

The rotation direction of the light extraction layer 40 is, for example, opposite to the first rotation direction, so that the light extraction layer 40 is capable of selectively transmitting the circularly polarized light CL1 of the first rotation direction. The rotation direction of the light extraction layer 40 is, for example, opposite to the second rotation direction, so that the light extraction layer 40 is capable of selectively reflecting the circularly polarized light CL2 of the second rotation direction.

In FIG. 4, the circularly polarized light CL1 of the first rotation direction is left-handed circularly polarized light, and the circularly polarized light CL2 of the second rotation direction is right-handed circularly polarized light.

In some examples, the anti-reflective layer 50 is located on the light extraction layer 40. The anti-reflection layer 50 is located on a side of the light extraction layer 40 away from the backplane. The anti-reflective layer 50 is used to reduce the reflectivity of the display panel 10 to external light, thereby improving the contrast of the display panel 10 and the display apparatus 1 to improve the display effect.

For example, the anti-reflection layer 50 may also convert circularly polarized light into linearly polarized light. For example, the anti-reflective layer 50 converts the circularly polarized light CL1 of the first rotation direction into linearly polarized light, and the polarization direction of the linearly polarized light is parallel to the direction of the transmission axis of the anti-reflective layer 50, so that the anti-reflective layer 50 is capable of transmitting the circularly polarized light CL1 of the first rotation direction.

For example, the natural light emitted by the light-emitting device 30 in the display panel 10 enters the light extraction layer 40 and is converted into the circularly polarized light CL1 of the first rotation direction and the circularly polarized light CL2 of the second rotation direction by the light extraction layer 40, and the light extraction layer 40 transmits the circularly polarized light CL1 of the first rotation direction and reflects the circularly polarized light CL2 of the second rotation direction.

The circularly polarized light CL1 of the first rotation direction that passes through the light extraction layer 40 may enter the anti-reflection layer 50 and emit passing through the anti-reflection layer 50; the circularly polarized light CL2 of the second rotation direction is reflected by the light extraction layer 40 to the light-emitting device 30 and is reflected by the conductive layer (e.g. the conductive layer where the first electrode is located, or the conductive layer where the second electrode is located) in the light-emitting device 30 and the rotation direction is changed, e.g., from the anticlockwise direction to the clockwise direction, and then enters the light extraction layer 40 again and passes through the light extraction layer 40 to enter the anti-reflective layer 50, and then emits passing through the anti-reflective layer 50. Thus, most of the light emitted by the light-emitting device 30 may emit through the light extraction layer 40 and the anti-reflective layer 50, thereby improving the display brightness of the display panel 10 and reducing the power consumption of the display panel. In the display panel 10 provided in the embodiments of the present disclosure, the light extraction layer 40 and the anti-reflection layer 50 are sequentially arranged on the side of the light-emitting device 30 away from the backplane. Thus, the light extraction layer 40 may be used to convert the light emitted by the light-emitting device 30 and entering the light extraction layer 40 into the circularly polarized light CL1 of the first rotation direction and the circularly polarized light CL2 of the second rotation direction, and to transmit the circularly polarized light CL1 of the first rotation direction and reflect the circularly polarized light CL2 of the second rotation direction. The reflected circularly polarized light CL2 of the second rotation direction enters the light-emitting device 30, and is reflected again by the first electrode or the second electrode in the light-emitting device 30 to change its rotation direction, and then enters the light extraction layer 40 again. Since the rotation direction of the circularly polarized light CL2 of the second rotation direction is changed and converted into the circular polarization light of the first rotation direction, the light may emit through the light extraction layer 40, and then continue to enter the anti-reflection layer 50 and is converted, by the anti-reflection layer 50, into the linearly polarized light parallel to the transmission axis direction of the anti-reflective layer 50, thereby allowing the circularly polarized light of the first rotation direction to pass through the anti-reflective layer 50 and emit. Thus, the display panel 10 can use the light extraction layer 40 to effectively utilize the light emitted by the light-emitting device 30 to improve the light extraction efficiency of the light-emitting device 30, so that about 80% of the light emitted by the light-emitting device 30 may transmit through the light extraction layer 40 and the anti-reflection layer 50. Compared with the above-mentioned implementation in which about 50% of the light emitted by the light-emitting device 30 is absorbed by the anti-reflection layer 50 and causes a loss, in the display panel provided by the embodiments of the present disclosure, it is possible to reduce the loss caused by a fact that part of the light emitted by the light-emitting device 30 is absorbed by the anti-reflective layer 50, thereby improving the display brightness of the display panel 10, reducing the power consumption of the display panel 10 and the display apparatus 1, and improving the display life of the display panel 10 and the display apparatus 1.

In addition, the anti-reflection layer 50 is capable of preventing the circularly polarized light CL2 of the second rotation direction from being transmitted. For example, it is assumed that the circularly polarized light CL2 of the second rotation direction enters the anti-reflection layer 50, the polarization direction of the circularly polarized light CL2 of the second rotation direction is perpendicular to the direction of the transmission axis of the anti-reflection layer 50, so that the circularly polarized light CL2 of the second rotation direction cannot pass through the anti-reflective layer 50. In this way, once the external light is incident on the anti-reflective layer 50, the anti-reflective layer 50 is able to block part of the light from passing through, thereby preventing the part of the light from entering the interior of the light-emitting device and being reflected by the conductive layer in the light-emitting device, thereby improving the anti-reflective ability of the display panel.

In some examples, the transmittance of the light extraction layer 40 to the light emitted by the light-emitting device 30 (which may be referred to as the transmittance of the light extraction layer 40) is greater than or equal to 35%.

For example, the transmittance of the light extraction layer 40 to the light emitted by the light-emitting device is 35%, 40%, 50%, 60% or 70%.

In some other examples, the reflectivity of the light extraction layer 40 to the light emitted by the light-emitting device 30 (which may be referred to as the reflectivity of the light extraction layer 40) is greater than or equal to 35%.

For example, the reflectivity of the light extraction layer 40 to the light emitted by the light-emitting device 30 is 35%, 42%, 50%, 60% or 75%.

In some other examples, the transmittance of the light extraction layer 40 to the light emitted by the light-emitting device 30 is greater than or equal to 35%, and the reflectivity of the light extraction layer 40 to the light emitted by the light-emitting device 30 is greater than or equal to 35%. It can be understood that a sum of the transmittance of the light extraction layer 40 for the light emitted by the light emitting device 30 and the reflectivity of the light extraction layer 40 to the light emitted by the light-emitting device 30 is not greater than 100%. For example, the transmittance of the light extraction layer 40 to the light emitted by the light-emitting device 30 is less than 50%, and the reflectivity of the light extraction layer 40 to the light emitted by the light-emitting device 30 is less than 50%.

With the above arrangement, it is possible to make the transmittance and/or reflectivity of the light extraction layer 40 is high, so as to improve the utilization rate of light by the light extraction layer 40, reduce the loss of the light emitted by the light-emitting device 30 by the light extraction layer 40, and reduce the loss of light emitted by the light-emitting device 30, which is beneficial to reducing the power consumption of the display panel 10 and the display apparatus 1.

For example, the display panel includes some light-emitting devices 30 for emitting blue light, and these light-emitting devices 30 may be referred to as blue light-emitting devices. In a case where the wavelength of the light emitted by the blue light-emitting device and incident on the light extraction layer 40 is in a range of 440 nm to 470 nm, in a range of at least one 10 nm within the range, the reflectivity of the light extraction layer 40 is greater than or equal to 35%.

It will be understood that light with a wavelength in the range of 440 nm to 470 nm is substantially blue light. That is to say, the reflectivity of the light extraction layer 40 to at least part of the blue light emitted by the light-emitting device 30 is greater than or equal to 35%.

For example, in the light emitted by the light-emitting device 30, the reflectivity of the light extraction layer 40 to blue light with a wavelength of the incident light between 440 nm and 450 nm is greater than or equal to 35%. Alternatively, the wavelength may be in a range of 445 nm to 455 nm, a range of 450 nm to 460 nm, a range of 455 nm to 465 nm, or a range of 460 nm to 470 nm.

For example, the display panel includes some light-emitting devices 30 for emitting green light, and these light-emitting devices 30 may be referred to as blue light-emitting devices. In a case where the wavelength of the light emitted by the green light-emitting device and incident on the light extraction layer 40 is in a range of 510 nm to 540 nm, in a range of at least one 10 nm within the range, the reflectivity of the light extraction layer 40 is greater than or equal to 35%.

It will be understood that light with a wavelength in the range of 510 nm to 540 nm is substantially green light. That is to say, the reflectivity of the light extraction layer 40 of at least part of the green light emitted by the light-emitting device 30 is greater than or equal to 35%.

For example, in the light emitted by the light-emitting device 30, the reflectivity of the light extraction layer 40 to green light with a wavelength of the incident light between 510 nm and 520 nm is greater than or equal to 35%. Alternatively, the wavelength may be in a range of 515 nm to 525 nm, a range of 520 nm to 530 nm, a range of 525 nm to 535 nm, or a range of 530 nm to 540 nm.

For example, the display panel includes some light-emitting devices 30 for emitting red light, and these light-emitting devices 30 may be referred to as red light-emitting devices. In a case where the wavelength of the light emitted by the red light-emitting devices and incident on the light extraction layer 40 is in a range of 610 nm to 645 nm, in a range of at least one 10 nm within the range, the reflectivity of the light extraction layer 40 is greater than or equal to 35%.

It can be understood that light with a wavelength in the range of 610 nm to 645 nm is substantially red light. That is to say, the reflectivity of the light extraction layer 40 to at least part of the red light is greater than or equal to 35%.

For example, in the light emitted by the light-emitting device 30, the reflectivity of the light extraction layer 40 to red light with a wavelength of incident light between 620 nm and 630 nm is greater than or equal to 35%. Alternatively, the wavelength may be in a range of 615 nm to 625 nm, a range of 625 nm to 635 nm, a range of 630 nm to 640 nm, or a range of 635 nm to 645 nm.

Therefore, it may be ensured that the reflectivity of the light extraction layer 40 to the light emitted by the light-emitting device 30 in different wavelength range is substantially the same, thereby ensuring that the brightness of the light of different color emitted by the display panel 10 is approximately the same. Moreover, it may be possible to reduce the probability of color shift in a case where the light emitted by the multiple light-emitting devices is combined to form white light.

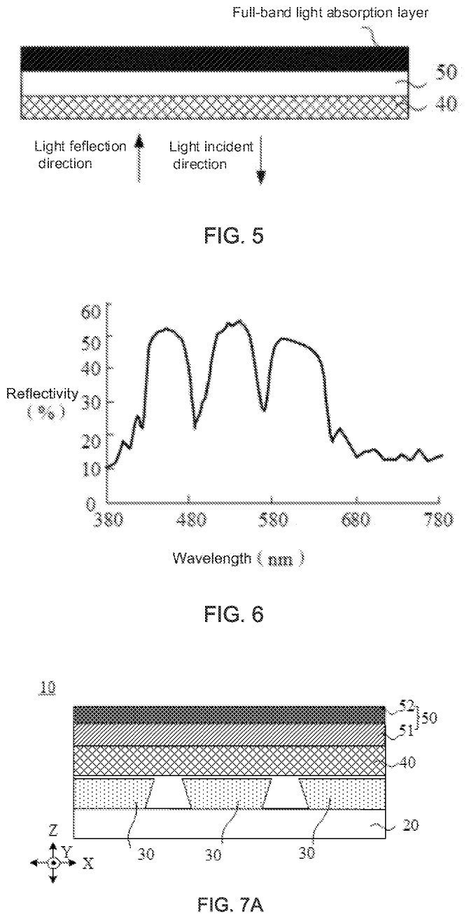

The inventors have carried out experiments on the reflectivity of the light extraction layer 40 to the light in different wavelength range, as shown in FIG. 5, a full-band light absorption layer is provided on a side of the light extraction layer 40 and the anti-reflection layer 50, and the reflectivity of the light extraction layer 40 to the light in different wavelength range is obtained by testing, and is plotted to obtain FIG. 6.

It can be seen from FIG. 6, the average reflectivity of the light extraction layer 40 to light in the visible light range is greater than or equal to 35%. Therefore, the display panel 10 provided by the above embodiments of the present disclosure may utilize the light extraction layer 40 to improve the utilization rate of light emitted by the light extraction layer 40, so that the brightness of the display panel 10 is improved, and the power consumption of the display panel 10 and the display apparatus 1 is reduced.

As shown in FIG. 6, in a case where the wavelength of the light incident on the light extraction layer 40 is in a range of 430 nm to 460 nm, the reflectivity of the light extraction layer 40 is greater than 35%; in a case where the wavelength of the light incident on the light extraction layer 40 is in a range of 520 nm to 530 nm, the reflectivity of the light extraction layer 40 is greater than 35%; in a case where the wavelength of the light incident on the light extraction layer 40 is in a range of 620 nm to 630 nm, the reflectivity of the light extraction layer 40 is greater than 35%.

In some embodiments, a material of light extraction layer 40 includes cholesteric liquid crystals.

For example, the cholesteric liquid crystals may convert the incident light into circularly polarized light, and capable of transmitting the circularly polarized light of a rotation direction opposite to that of the circularly polarized light, such as the circularly polarized light CL1 of the first rotation, and capable of reflecting the circularly polarized light of a rotation direction the same as that of the circularly polarized light, such as the circularly polarized light CL2 of the second rotation direction.

With the above arrangement, it is possible to improve the screening efficiency of the light extraction layer 40, so that more circularly polarized light is able to pass through the light extraction layer 40 and emit, and more circularly polarized light is able to be reflected by the light extraction layer 40 and then pass through the light emitting device 30 and emit. Thus, it is possible to improve the utilization rate of the light emitted by the light-emitting device 30, thereby increasing the luminous brightness of the display panel 10, reducing the power consumption of the display panel 10, and prolonging the service life of the display panel 10 and the display apparatus 1.

It can be understood that the display panel 10 has a display region, and the display region is a region of the display panel 10 used to display images. The light extraction layer 40 composed of cholesteric liquid crystals covers the entire display region of the display panel 10. In this way, the light emitted by the multiple light-emitting devices 30 in the display panel may pass through the cholesteric liquid crystals and then emit, thereby improving the utilization rate of the light emitted by the light-emitting devices 30, and reducing the power consumption of the display panel 10.

Cholesteric liquid crystals have multiple layers of molecules, molecules in each layer are arranged in a same direction, but the molecules in two adjacent layers are arranged in a slightly rotated direction, and stacked into a spiral structure, and the cholesteric liquid crystals have a microscopic spiral structure. In a case where the arrangement direction of one layer of molecules rotates 360° and returns to the original direction, a distance between the two layers with the same molecular arrangement is referred to as a helical pitch of the cholesteric liquid crystals. Cholesteric liquid crystals are generally ester compounds formed by reacting cholesterol as the main raw material and certain organic acids (e.g., oleic acid, benzoic acid, or nonanoic acid).

For example, cholesteric liquid crystals have different helical pitches, and the wavelengths of light they can reflect are also different. That is to say, cholesteric liquid crystals with different helical pitches may selectively reflect light of different wavelengths.

The light extraction layer 40 is arranged in various manners, which may be set according to actual needs, and is not limited in the present disclosure.

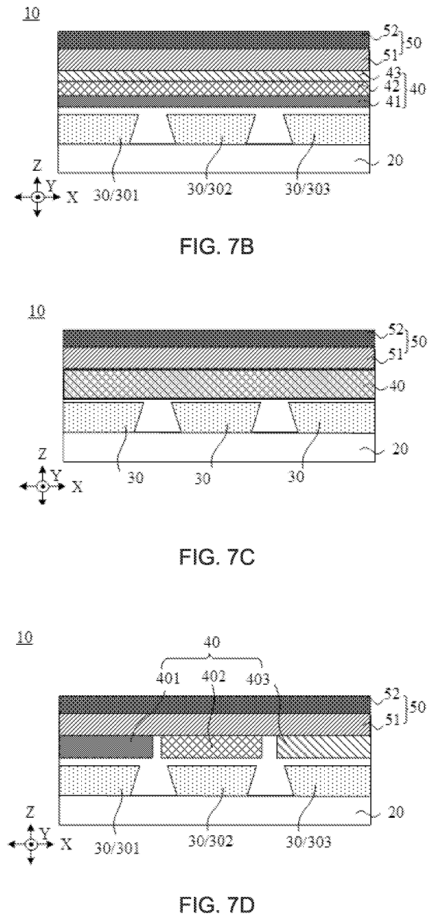

In some embodiments, as shown in FIGS. 7A to 7D, the material of the light extraction layer 40 includes at least one type of cholesteric liquid crystals. In a case where the material of the light extraction layer 40 includes at least two types of cholesteric liquid crystals, the helical pitch of the at least two types of cholesteric liquid crystals are not equal.

In some examples, as shown in FIG. 7A, the material of light extraction layer 40 includes one type of cholesteric liquid crystal. That is, the helical pitch of the material of cholesteric liquid crystals in the light extraction layer 40 is substantially equal. The helical pitch of the material of cholesteric liquid crystals in the light extraction layer 40 is within a certain small range, or the helical pitch of the material of cholesteric liquid crystals in the light extraction layer 40 is the same.

The cholesteric liquid crystals have high reflectivity and transmittance for light in a certain wavelength range emitted by the plurality of light-emitting devices 30.

For example, in a case where the helical pitch of the cholesteric liquid crystals is a first size, the light extraction layer 40 formed by the cholesteric liquid crystals only have high reflectivity and transmittance for the red light emitted by the light-emitting devices, so that the light extraction efficiency of red light-emitting devices may be improved. For another example, in a case where the helical pitch of the cholesteric liquid crystals is a second size, the light extraction layer 40 formed of the cholesteric liquid crystals only have high reflectivity and transmittance for the green light emitted by the light-emitting devices, so that the light extraction efficiency of the green light-emitting devices may be improved. For another example, in a case where the helical pitch of the cholesteric liquid crystals is a third size, the light extraction layer 40 formed by the cholesteric liquid crystals only have high reflectivity and transmittance for the blue light emitted by the light-emitting devices, so that the light extraction efficiency of blue light-emitting devices may be improved. Therefore, the light extraction layer 40 may be made to have high reflectivity and transmittance for light in a certain wavelength range, thereby improving the brightness of the light in this wavelength range. The first size, second size and third size are not equal.

In some other examples, as shown in FIG. 7B, in a case where the material of the light extraction layer 40 includes at least two types of cholesteric liquid crystals, the light extraction layer 40 includes at least two light extraction sub-layers stacked in sequence; the at least two light extraction sub-layers include a first light extraction layer 41 and a second light extraction layer 42; a helical pitch of cholesteric liquid crystals in the first light extraction layer 41 and a helical pitch of cholesteric liquid crystals in the second light extraction layer 42 are not equal.

For example, as shown in FIG. 7B, the light extraction layer 40 includes a first light extraction layer 41, a second light extraction layer 42, and a third light extraction layer 43 that are stacked in sequence. The helical pitch of the cholesteric liquid crystals in the first light extraction layer 41, the helical pitch of the cholesteric liquid crystals in the second light extraction layer 42, and the helical pitch of the cholesteric liquid crystals in the third light extraction layer 43 are not equal.

The helical pitch of the cholesteric liquid crystals in the first light extraction layer 41, the helical pitch of the cholesteric liquid crystals in the second light extraction layer 42, and the helical pitch of the cholesteric liquid crystals in the third light extraction layer 43 have various corresponding relations with the wavelength of red light, the wavelength of green light, and the wavelength of blue light, which may be set according to needs, and may not be limited in the present disclosure.

For example, the helical pitch of the cholesteric liquid crystals in the first light extraction layer 41 corresponds to the wavelength of red light, and the cholesteric liquid crystals in the first light extraction layer 41 may reflect red light; the helical pitch of the cholesteric liquid crystals in the second light extraction layer 42 corresponds to the wavelength of green light, and the cholesteric liquid crystals in the second light extraction layer 42 may reflect green light; the helical pitch of the cholesteric liquid crystals in the third light extraction layer 43 corresponds to the wavelength of blue light, and the cholesteric liquid crystals in the third light extraction layer 43 may reflect blue light.

For another example, the helical pitch of the cholesteric liquid crystals in the first light extraction layer 41 corresponds to the wavelength of green light, and the cholesteric liquid crystals in the first light extraction layer 41 may reflect green light; the helical pitch of the cholesteric liquid crystals in the second light extraction layer 42 corresponds to the wavelength of red light, and the cholesteric liquid crystals in the second light extraction layer 42 may reflect red light; the helical pitch of the cholesteric liquid crystals in the third light extraction layer 43 corresponds to the wavelength of blue light, and the cholesteric liquid crystals in the third light extraction layer 43 may reflect blue light.

Therefore, the light extraction layer 40 may reflect light of different colors or different wavelengths emitted by the plurality of light-emitting devices 30, thereby accurately controlling the reflection of light by the light extraction layer 40 to improve the utilization rate of the light emitted by the light-emitting devices 30, and adjust the brightness of the light of different colors emitted by the light-emitting devices 30 to be substantially the same. Thus, it is possible to reduce the probability of color shift in the white light synthesized by the interaction of the light of different colors.

In some other examples, as shown in FIG. 7C, in the case where the material of the light extraction layer 40 includes at least two types of cholesteric liquid crystals, the at least two types of cholesteric liquid crystals include first liquid crystals and second liquid crystals; the first liquid crystals are evenly distributed in the light extraction layer, the second liquid crystals are evenly distributed in the light extraction layer, and a distribution density of the first liquid crystals in the light extraction layer 40 is substantially equal to a distribution density of the second liquid crystals in the light extraction layer 40.

For example, the material of the light extraction layer 40 includes at least two types of cholesteric liquid crystal materials with different helical pitches. The at least two types of cholesteric liquid crystals with different helical pitches are evenly distributed at different positions of the light extraction layer 40, or in other words, the distribution densities of the at least two types of cholesteric liquid crystals with different helical pitches at different positions of the light extraction layer 40 are substantially the same. For example, a blending process may be used to blend the at least two types of cholesteric liquid crystals with different helical pitches to form the light extraction layer.

Considering an example in which the light extraction layer 40 includes three types of cholesteric liquid crystals, the three types of cholesteric liquid crystals with different helical pitches are respectively the first liquid crystals, the second liquid crystals and the third liquid crystals. For example, the first liquid crystals have a high reflectivity and transmittance for the red light emitted by the light-emitting devices, thereby reflecting or transmitting the red light; the second liquid crystals have a high reflectivity and transmittance for the green light emitted by the light-emitting devices, thereby reflecting or transmitting the green light; the third liquid crystals have a high reflectivity and transmittance for the blue light emitted by the light-emitting devices, thereby reflecting or transmitting the blue light. Thus, it is possible to accurately control the reflection of light by using the light extraction layer 40 to improve the luminous efficiency of the light emitted by the light-emitting devices 30 and adjust the brightness of the light of different colors emitted by the light-emitting devices 30 to be substantially the same, thereby reducing the probability of color shift in the white light synthesized by the interaction of the light of different colors.

In some other examples, as shown in FIG. 7D, in a case where the material of the light extraction layer 40 includes at least two types of cholesteric liquid crystals, in the light extraction layer 40, the helical pitches of cholesteric liquid crystals corresponding to the light-emitting devices 30 with different light-emitting colors are not equal.

For example, the light extraction layer 40 may include a plurality of first light extraction portions 401, a plurality of second light extraction portions 402, and a plurality of third light extraction portions 403; the helical pitches of the cholesteric liquid crystals in the first light extraction portion 401, the second light extraction portion 402, and the third light extraction portion 403 are different. One first light extraction portion 401 corresponds to one red light-emitting device 301. That is, an orthographic projection of a red light-emitting device 301 on the backplane 20 is located within an orthographic projection of a first light extraction portion 401 on the backplane 20, and the light emitted by the red light-emitting device 301 may be projected onto the corresponding first light extraction portion 401, so that the first light extraction portion 401 is able to reflect or transmit the red light emitted by the red light-emitting device 301. One second light extraction portion 402 corresponds to one green light-emitting device 302. That is, an orthographic projection of a green light-emitting device 302 on the backplane 20 is located within an orthographic projection of a second light extraction portion 402 on the backplane 20, and the light emitted by the green light-emitting device 302 may be projected onto the corresponding second light extraction portion 402, so that the second light extraction portion 402 is able to reflect or transmit the green light emitted by the green light-emitting device 302. One third light extraction portion 403 corresponds to one blue light-emitting device 303. That is, an orthographic projection of a blue light-emitting device 303 on the backplane 20 is located within an orthographic projection of a third light extraction portion 403 on the backplane 20, and the light emitted by the blue light-emitting device 303 may be projected onto the corresponding third light extraction portion 403, so that the third light extraction portion 403 is able to reflect or transmit the blue light emitted by the blue light-emitting device 303.

For example, in the light extraction layer 40, the helical pitches of the cholesteric liquid crystals corresponding to the light-emitting devices 30 with the same light-emitting color may be substantially the same. The helical pitches of the cholesteric liquid crystals in the plurality of first light extraction portions 401 are substantially the same. The helical pitches of the cholesteric liquid crystals in the plurality of second light extraction portions 402 are substantially the same. The helical pitches of the cholesteric liquid crystals in the plurality of third light extraction portions 403 are substantially the same. The description “substantially the same” means that the helical pitches of cholesteric liquid crystals at different positions are equal, or a difference between the helical pitches of cholesteric liquid crystals at different positions is less than or equal to 5% of the minimum helical pitch of the cholesteric liquid crystals.

In a case where the helical pitch of the cholesteric liquid crystals matches the wavelength of the light emitted by the light-emitting device, the cholesteric liquid crystals capable of selectively reflecting light and transmitting light, and have a high reflectivity and transmittance to the light.

Since the wavelengths of light emitted by different light-emitting devices are different, with the above arrangement, the cholesteric liquid crystals in the portions of the light extraction layer 40 corresponding to the different light-emitting devices 30 may accurately transmit or reflect light of different wavelengths. Therefore, the transmittance and reflectivity of the light extraction layer to the light of different wavelengths emitted by the different light-emitting devices 30 may be accurately controlled, so as to improve the utilization rate of the light emitted by the different light-emitting devices 30 and adjust the brightness of the light of different colors emitted by the light-emitting devices to be substantially the same, thereby reducing the probability of color shift in the white light synthesized by the interaction of light of different colors.

In some examples, the display panel 10 further includes a first connection layer located on a side of the light extraction layer 40 proximate to the anti-reflection layer 50, and/or a second connection layer located on a side of the light extraction layer 40 away from the anti-reflection layer 50.

For example, both the first connection layer and the second connection layer play a bonding role. The first connection layer is used to connect the anti-reflection layer 50 and the light extraction layer 40, and the second connection layer is used to connect the light extraction layer 40 and the light-emitting devices 30.

In some embodiments, as shown in FIG. 7A, the anti-reflective layer 50 includes at least a ¼ wave plate and a polarizing layer 52. The ¼ wave plate is located between the polarizing layer 52 and the light extraction layer 40.

In some examples, the ¼ wave plate causes light incident thereon to undergo a phase delay of (2n−1) λ/4, where λ is the wavelength of the incident light, such as the value of λ is in a range of 520 nm to 570 nm; n is a positive integer, such as n=1, 2, 3 . . . .

Of course, in a case where the wavelength λ of the incident light is in a range of 460 nm to 630 nm, the ¼ wave plate may also cause the light incident thereon to undergo a phase delay of (2n−1)λ/4.

For example, as shown in FIG. 4, the circularly polarized light that passes through the light extraction layer 40 is converted into linearly polarized light by the ¼ wave plate after being incident on the ¼ wave plate.

In some examples, the polarizing layer 52 may transmit light in a direction parallel to a transmission axis of the polarizing layer 52 and reflect light in a direction perpendicular to the transmission axis of the polarizing layer 52. Therefore, the amount of external light entering the display panel 10 may be reduced, and the reflection of external light by the conductive layer in the display panel 10 may also be reduced, thereby improving the contrast of the display panel 10. In addition, the display panel 10 may also be caused to emit the polarized light to avoid the halo phenomena in the display panel 10.

In some embodiments, a transmittance of the polarizing layer 52 to visible light is greater than or equal to 40%.

For example, the transmittance of the polarizing layer 52 is 40%, 45%, 52%, 62%, or 75%.

With the above arrangement, the loss of light caused by the polarizing layer 52 may be reduced, the light extraction efficiency of the display panel 10 may be improved, the light consumption may be reduced, and the power consumption of the display panel 10 and the display apparatus 1 may be reduced.

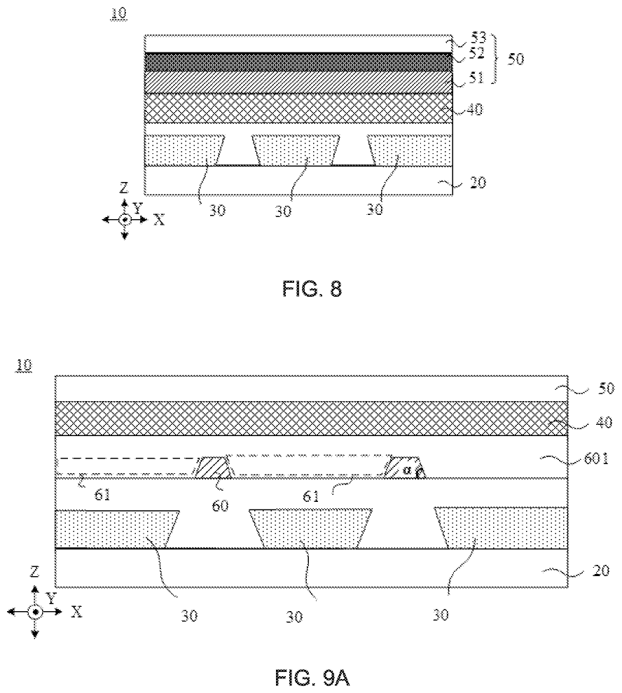

In some embodiments, as shown in FIG. 8, the anti-reflective layer 50 further includes a light absorption layer 53. The light absorption layer 53 is stacked on the ¼ wave plate or the polarizing layer 52.

For example, the light absorption layer 53 may be located between the ¼ wave plate and the polarizing layer 52, or the light absorption layer 53 may be located on a side of the ¼ wave plate away from the polarizing layer 52, or the light absorption layer 53 may be located on a side of the polarizing layer 52 away from the ¼ wave plate.

For example, the light absorption layer 53 is used to absorb light with a wavelength in a range below 450 nm, for example, light with a wavelength of 445 nm, 440 nm or 435 nm.

Light with the wavelength in the range below 450 nm is generally blue light with short wavelength.

With the above arrangement, the light absorption layer 53 may be used to absorb the blue light with short wavelength filtered by the light extraction layer 40 to prevent the blue light with short wavelength from emitting from the display panel and prevent the blue light with short wavelength from being entering the human eye and causing damage to the human eye. Thus, the display panel 10 and the display apparatus 1 have an eye protection function.

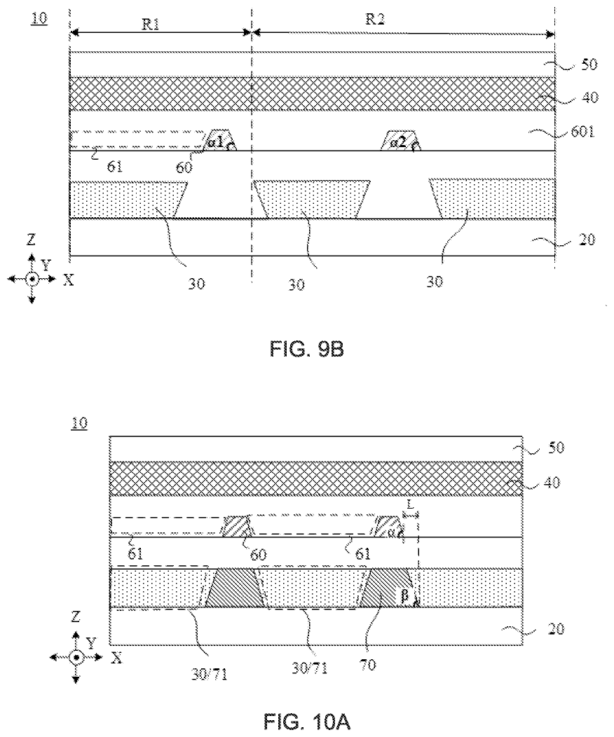

In some embodiments, as shown in FIG. 9A, the display panel 10 further includes a light shielding layer 60 provided between the plurality of light-emitting devices 30 and the light extraction layer 40. The light shielding layer 60 has a plurality of first openings 61. An orthogonal projection of a light-emitting device 30 on the backplane 20 and an orthogonal projection of a first opening 61 on the backplane 20 have an overlapping region therebetween.

Here, the orthographic projection of the light-emitting device 30 on the backplane 20 refers to an orthographic projection of an effective light-emitting region of the light-emitting device 30 on the backplane 20. The effective light-emitting region of the light-emitting device 30 is a region defined by a second opening in a definition layer of the light-emitting device 30.

For example, light emitted by a light-emitting device 30 is incident on the region corresponding to the corresponding first opening 61.

For example, the orthographic projection of the light-emitting device 30 on the backplane 20 is within the orthographic projection of the first opening 61 on the backplane 20.

The light shielding layer 60 may absorb or block the light incident thereon to prevent the light from transmitting, thereby achieving a light-shielding effect; the first opening 61 in the light shielding layer 60 may allow part of the light emitted by the corresponding light-emitting device 30 to pass through. For example, the plurality of light-emitting devices 30 correspond to the plurality of first openings 61 in one-to-one correspondence.

With the above arrangement, among the light emitted by all the light-emitting devices 30, light with a large viewing angle (here, the light with the large viewing angle referring to the light whose emission direction having a large included angle (e.g., the included angle is greater than 45°) with the normal line of the backplane 20) is blocked by the light shielding layer 60, thereby avoiding crosstalk between the light emitted by adjacent light-emitting devices 30 to improve the display effect of the display panel 10. Moreover, the arrangement of the light shielding layer 60 may also reduce the reflection effect of the display panel on external light, so that the display panel 10 has a high contrast in the bright viewing field, and the display effect of the display panel 10 is improved. In addition, the display panel 10 may also be made to emit light with a small viewing angle, so that the brightness of the picture displayed by the display panel 10 viewed by the user at a small viewing angle is great, so that the brightness of the display picture viewed by the user at other viewing angles is small. Thus, the display panel 10 has a certain privacy protection function. It can be understood that in different regions of the display panel, the angles between side walls of the first opening 61 in the light shielding layer 60 and a plane where the backplane 20 is located may or may not be equal.

In some examples, as shown in FIG. 9B, the display panel 10 has a first region R1 and a second region R2. An included angle α1 between a side wall of at least one first opening 61 in the first region R1 and the plane where the backplane 20 is located is not equal to an included angle α2 between a side wall of at least one first opening 61 in the second region R2 and the plane where the backplane 20 is located.

For example, the first region R1 and the second region R2 may be adjacent or not adjacent.

For example, in a case where the display panel 10 is a full-screen display panel, and the full-screen display panel includes a full display with camera (FDC), in the display panel 10, the first region R1 is a display region of the display panel directly opposite to the camera, and the second region R2 is a display region other than the first region R1. The included angle α1 between the side wall of each of the plurality of first openings 61 located in the first region R1 and the plane where the backplane 20 is located is set to be smaller than the included angle α2 between the side wall of at least one first opening 61 located in the second region R2 and the plane where the backplane 20 is located, so that the light shielding layer 60 is made to block less of the light incident to the camera through the first region R1, so as to enable the camera to receive enough external light to achieve the camera function.

For another example, in a case where the display panel 10 is applied as a transparent display panel, the included angle α1 between the side wall of the at least one first opening 61 in the first region R1 and the plane where the backplane 20 is located and the included angle α2 between the side wall of the at least one first opening 61 in the second region R2 and the plane where the backplane 20 is located may be set according to the actual situation.

With the above arrangement, the first openings 61 in different regions of the display panel 10 may be designed differentially, so as to adjust the amount of light emitted in different regions of the display panel 10 to ensure that the amount of light emitted in different regions of the display panel 10 is substantially the same, and thus the display effect of the display panel 10 is ensured.

In some embodiments, as shown in FIG. 9A, an included angle α between the sidewall of the first opening 61 and a plane where the backplane 20 is located is an acute angle.

For example, the included angle between the side wall of the first opening 61 and the plane where the backplane 20 is located may be 25°, 30°, 35°, 37° or 40°.

With the above arrangement, it is possible to avoid a situation that the entire light extraction layer 40 located on the light shielding layer 60 is easily punctured caused by a large included angle between the side wall of the first opening 61 and the plane where the backplane 20 is located, which is convenient to manufacture the light extraction layer 40 and the anti-reflective layer 50 that are located on the light shielding layer 60.

In some examples, as shown in FIG. 9A, the display panel 10 further includes a planarization layer 601 located on the side of the light shielding layer 60 away from the backplane 20.

For example, a surface of the planarization layer 601 away from the backplane 20 is a flat surface, and the light extraction layer 40 is disposed on the flat surface, which facilitates the manufacturing of the light extraction layer 40.

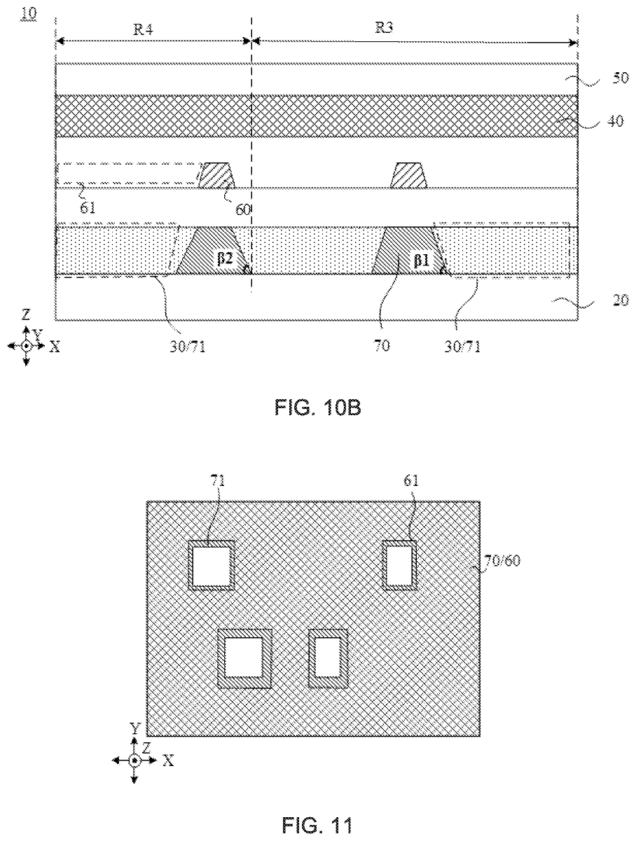

In some embodiments, as shown in FIG. 10A, the display panel 10 further includes a definition layer 70 located between the backplane 20 and the light shielding layer 60.

In some examples, the definition layer 70 has a plurality of second openings 71, and one second opening 71 is arranged directly opposite to one first opening 61 in a direction perpendicular to the plane where the backplane 20 is located.

An orthogonal projection of a second opening 71 on the backplane 20 and an orthogonal projection of a first opening 61 on the backplane 20 have an overlapping region.

A first opening 61 corresponds to a light-emitting device 30, and a second opening 71 is arranged directly opposite to a first opening 61, so that a second opening 71 is also arranged corresponding to a light-emitting device 30.

It will be understood that in different regions of the display panel 10, the included angles between side walls of the second opening 71 in the definition layer 70 and the plane where the backplane 20 is located may or may not be equal.

In some examples, as shown in FIG. 101B, the display panel 10 has a third region R3 and a fourth region R4. An included angle β1 between a side wall of at least one second opening 71 in the third region R3 and the plane where the backplane 20 is located is not equal to an included angle β2 between a side wall of at least one second opening 71 in the fourth region R4 and the plane where the backplane 20 is located.

For example, the included angle β1 between the side wall of the at least one second opening 71 in the third region R3 and the plane where the backplane 20 is located is greater than the included angle β2 between the side wall of the at least one second opening 71 in the fourth region R4 and the plane where the backplane 20 is located.

With the above arrangement, for example, in a case where the display panel 10 is a full-screen display or a transparent display panel or a double-sided display panel, the second openings 71 in different regions of the display panel 10 may be designed differently, so as to adjust the amount of light emitted from different regions of the display panel 10 to ensure that the amount of light emitted from different regions of the display panel 10 is substantially the same, and thus the display effect of the display panel 10 is ensured.

In the same region of the display panel 10, such as the third region R3, the relationship between the included angle α between the side wall of the first opening 61 and the plane where the backplane 20 is located and the included angle β between the side wall of the second opening 71 and the plane where the backplane 20 is located may be set according to actual needs, and the embodiments of the present disclosure do not limit thereto.

In some examples, as shown in FIG. 10A, the included angle α between the side wall of the first opening 61 and the plane where the backplane 20 is located is greater than the included angle β between the side wall of the second opening 71 and the plane where the backplane 20 is located.

With the above arrangement, it is possible to use the light shielding layer 60 having the first openings 61 to block the large-angle light emitted from the light-emitting device 30, so that the light-emitting angle of the display panel 10 is small, thereby allowing the user to view the display image at a small viewing angle; however, the brightness of the display image viewed by the user at a large viewing angle is small, or the user cannot view the display image at a large viewing angle. Thus, the display panel 10 may achieve a good privacy protection function, especially in a case where the display panel is used in vehicle display.

In some other examples, the included angle α between the side wall of the first opening 61 and the plane where the backplane 20 is located is smaller than the included angle β between the side wall of the second opening 71 and the plane where the backplane 20 is located.

With the above arrangement, the light shielding layer 60 having the first openings 61 is made to block less large-angle light emitted by the light-emitting device 30, which makes the display panel 10 have a large light-emitting angle, thereby allowing the user capable of viewing the light at different viewing angles. Therefore, in a case where the display panel is in environmental conditions such as outdoors, the display panel may enable more users at different viewing angles to view the display image, thereby achieving a good display effect.

In some other examples, the included angle α between the side wall of the first opening 61 and the plane where the backplane 20 is located is equal to the included angle β between the side wall of the second opening 71 and the plane where the backplane 20 is located.

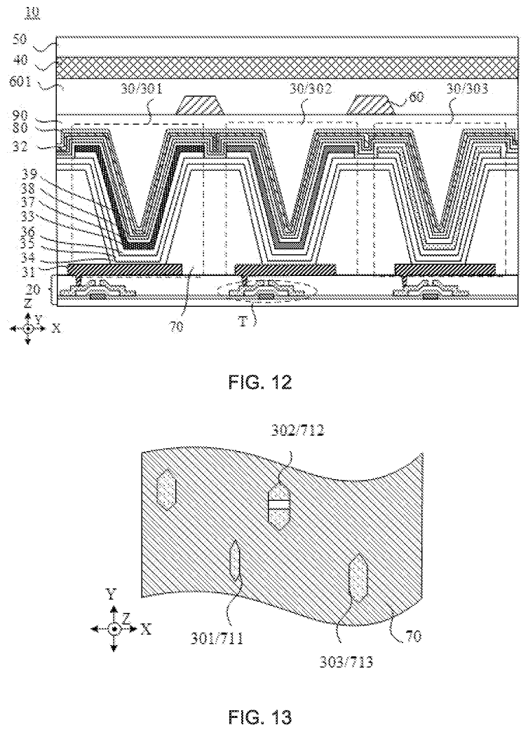

For example, as shown in FIG. 12, the light-emitting device 30 includes at least a light-emitting layer 33. A light-emitting layer 33 is located at least in a second opening 71.

For example, the light-emitting layer 33 is located in the second opening 71. For another example, a portion of the light-emitting layer 33 is located in the second opening 71, another portion of the light-emitting layer 33 laps the definition layer 70, and two adjacent light-emitting layers 33 are disconnected.

For example, the definition layer 70 separates the light-emitting layers 33 of adjacent light-emitting devices 30, thereby reducing the probability of crosstalk between the large-angle light emitted by all the light-emitting devices 30.

As shown in FIG. 10A, for example, the included angle β between the side wall of the second opening 71 and the plane where the backplane 20 is located is less than or equal to 35°.

For example, the angle β between the side wall of the second opening 71 and the plane where the backplane 20 is located may be 20°, 25°, 27°, 32° or 35°.

With the above arrangement, it is possible to ensure the flatness of the film layer (e.g., a second electrode 32 mentioned below) formed on the definition layer 70 to avoid a situation that the film layer is disconnected caused by a fact that the included angle between the side wall of the second opening 71 and the plane where the backplane 20 is located is too large, thereby improving the stability and accuracy of a signal transmitted by the film layer and improving the display effect of the display panel 10.

In some embodiments, a material of the definition layer 70 includes a light absorbing material, and/or a material of the light shielding layer 70 includes a light absorbing material.

In some examples, the material of the definition layer 70 includes a light absorbing material. Therefore, part of the light emitted by the light-emitting device 30 that is incident on the definition layer 70 may be absorbed by the definition layer 70.

In some other examples, the material of the light shielding layer 60 includes a light shielding material. Therefore, the light shielding layer 60 may be used to absorb large-angle light to ensure that this part of the light does not emit, thereby ameliorating or even avoiding the crosstalk phenomenon between the light emitted by the adjacent light-emitting devices 30, and also allowing the user to view the image displayed on the display panel 10 at a small viewing angle. Thus, the display panel 10 has a certain privacy protection function.

In some other examples, the material of the definition layer 70 includes a light absorbing material, and the material of the light shielding layer 60 includes a light shielding material.

For example, the material of the definition layer 70 is the same as the material of the light shielding layer 60.

With the above arrangement, the definition layer 70 or the light shielding layer 60 formed of the light absorbing material may be used to ameliorate or even avoid the crosstalk phenomenon between the light emitted by adjacent light-emitting devices 30, and allow the user to view the image displayed on the display panel 10 at a small viewing angle (e.g., a substantially front-facing viewing angle), so that the display panel 10 and the display apparatus 1 have a certain privacy protection function.

In some embodiments, the absorbance of the light shielding material is greater than or equal to 0.5.

For example, the absorbance represents the degree of light absorption of a material per unit thickness. The description that the absorbance is greater than or equal to 50% means that the intensity of light decreases by at least 50% after passing through the light absorbing material per micron thickness.

For example, the absorbance of the light absorbing material is 50%, 60%, 80%, 90% or 100%.

The absorbance of the light absorbing material is set within the above range, the definition layer 70 or the light shielding layer 60 may be used to absorb the large-angle light of different colors emitted by the adjacent light-emitting devices 30, thereby ameliorating or avoiding the crosstalk phenomenon between the light of different colors. Thus, the display effect of the display panel 10 and the display apparatus 1 is improved.

In some embodiments, as shown in FIGS. 10A and 11, the orthographic projection of the second opening 71 on the backplane is located within the orthographic projection of the first opening 61 directly opposite the second opening 71 on the backplane.

For example, a border line of the orthographic projection of the second opening 71 on the backplane 20 is located within a border line of the orthographic projection of the first opening 61 on the backplane 20 that is directly opposite the second opening 71, and the two border lines have a certain distance therebetween.

For example, in orthographic projections on a plane where the light extraction layer 40 is located, the orthographic projection of the definition layer 70 covers the orthographic projection of the light shielding layer 60.

With the above arrangement, it may be possible to avoid a phenomenon that the light shielding layer 60 blocks or absorbs a large amount of light incident through the second opening 71 of the definition layer 70 and weakens the intensity of the emitted light, thereby improving the brightness of the display panel 10 and reducing the power consumption of the display panel 10 and the display apparatus 1.

In some embodiments, as shown in FIG. 10A, the maximum distance L between a border line of the orthographic projection of the second opening 71 on the backplane 20 and a border line of the orthographic projection of the first opening 61 directly opposite to the second opening 71 on the backplane 20 is less than or equal to ⅓ of the maximum size of the orthographic projection of the second opening 71 on the backplane 20.

For example, the maximum distance L between the border line of the orthographic projection of the second opening 71 on the backplane 20 and the orthographic projection of the first opening 61 directly opposite the second opening 71 on the backplane 20 is ⅓, 2/7, ¼, 2/9 or ⅕ of the maximum size of the orthographic projection of the second opening 71 on the backplane 20.

Since the included angle between the side wall of the first opening 61 and the plane where the backplane 20 is located is an acute angle rather than a right angle, the orthographic projection of the first opening 61 on the backplane 20 has two contour lines, and the two contour lines are an outer contour line and an inner contour line, and the inner contour line is located within the outer contour line. The border line of the orthographic projection of the first opening 61 on the backplane 20 refers to the inner contour line of the orthographic projection of the first opening 61 on the backplane 20. Similarly, since the included angle between the side wall of the second opening 71 and the plane where the backplane 20 is located is an acute angle rather than a right angle, the orthographic projection of the second opening 71 on the backplane 20 has two contour lines, and the two contour lines are an outer contour line and an inner contour line, and the inner contour line is located within the outer contour line. The border line of the orthographic projection of the second opening 71 on the backplane 20 refers to the inner contour line of the orthographic projection of the second opening 71 on the backplane 20.

Any two points on the border line of the orthographic projection of the first opening 61 on the backplane 20 have a certain distance therebetween. The term “maximum distance” refers to a distance between two points with the largest distance on the border line of the orthographic projection of the first opening 61 directly opposite the second opening 71 on the backplane 20.

For example, the orthographic projection of the second opening 71 on the backplane 20 has various shapes, which may be selected according to the actual situation, and may be not limited in the present disclosure.

For example, the orthogonal projection of the second opening 71 on the backplane 20 may be in a shape of a circle, a triangle, a rectangle or the like. Considering an example in which the orthographic projection of the second opening 71 on the backplane 20 is in a shape of a hexagon, the maximum size of the orthographic projection of the second opening 71 on the backplane 20 may be the size of the longest diagonal of the hexagon.

With the above arrangement, the light shielding layer 60 may not only have a certain blocking effect on the light emitted by each light-emitting device 30 and reduce the crosstalk between the light emitted by adjacent light-emitting devices, but also enable the light with a large viewing angle emitted by the light-emitting devices 30 to emit from the first openings 61 in the light shielding layer 60, which meets the needs of user to view the display image of the display panel 10 within a large viewing angle, so that the user capable of viewing the display image of the display panel 10 normally at a side viewing angle (or the brightness of the display image of the display panel is large at the side viewing angle). Thus, it is possible to facilitate the display panel to achieve a shared state display and avoid a narrow viewing angle of the user or a small display brightness at a large viewing angle caused by a fact that the light shielding layer 60 blocks or absorbs the light within a large angle range, so as to avoid affecting the viewing experience at a side viewing angle.

It will be understood that the light-emitting devices 30 may be top emission light-emitting devices. The light emitted by the top emission light-emitting device emit toward the side away from the backplane 20. Hereinafter, the description will be made by taking an example in which the first electrode 31 is an anode and the second electrode 32 is a cathode.

For example, as shown in FIG. 12, in the light-emitting device 30, a material of the second electrode 32 may be a semi-transparent material or a light-transmitting material, and the reflectivity of the first electrode 31 is greater than or equal to 85%.

For example, the second electrode 32 may transmit at least part of the light incident on its surface.

For example, the reflectivity of the first electrode 31 for light in the visible light wavelength is in a range of 85% to 95%. Therefore, the first electrode 31 may be used to reflect as much light as possible emitted by the light-emitting device 30, thereby improving the light extraction efficiency of the light-emitting device 30.

For example, the reflectivity of the first electrode 31 is 85%, 90%, 92%, 94%, or 95%.

For example, the light-emitting layer 33 emits natural light under the voltage provided by the first electrode 31 and the second electrode 32. Part of the light emitted by the light-emitting layer 33 may emit through the second electrode 32. Another part of the light emitted by the light-emitting layer 33 may be reflected by the first electrode 31 and then enter the second electrode 32 and emit. In addition, the circularly polarized light CL2 of the second rotation direction reflected by the light extraction layer 40 will also pass through the second electrode 32 and the light-emitting layer 33 and then enter the first electrode 31, and will be changed in the rotation direction by the first electrode 31 and reflected to the second electrode 32, then, enters the light extraction layer 40 again after passing through the second electrode 32 again, and emits passing through the light extraction layer 40.

With the above arrangement, the light transmittance of the second electrode 32 may be high, and the reflectivity of the first electrode 31 may be high, which reduces the loss of the light emitted by the light-emitting device 30 when incident on the first electrode 31 or the second electrode 32, thereby improving the utilization rate of the light emitted by the light-emitting layer 33 and reducing the light consumption of the light-emitting device 30. Thus, it is possible to improve the display brightness of the display panel 10 and the display apparatus 1, and reduce the power consumption of the display panel 10 and the display apparatus 1.

In some examples, the material of the first electrode 31 is a material with a high work function, which is beneficial to improving the light extraction efficiency of the light emitting device 30.

For example, the first electrode 31 may be composed of multiple composite film layers. The materials of the multiple composite film layers may include a metal oxide material and a metal material, such as a composite film layer of silver (Ag) and indium tin oxide (ITO), or a composite film layer of Ag and indium zinc oxide (IZO). A thickness of the metal material may be in a range of 80 nm to 200 nm, inclusive, and a thickness of the metal oxide material may be in a range of 5 nm to 10 nm, inclusive.

For example, the material of the second electrode 32 may be metal element, such as magnesium (Mg), Ag or aluminum (Al).

For another example, the material of the second electrode 32 may be metal alloy, such as silver-magnesium alloy (Mg—Ag). In a case where the material of the second electrode 32 is silver-magnesium alloy, a mass ratio of magnesium to silver in magnesium-silver alloy is in a range of 1:9 to 3:7, inclusive. The transmittance of the second electrode 32 made of the metal alloy material for light with a wavelength of 530 nm is in a range of 50% to 60%, inclusive.

For another example, the material of the second electrode 32 may be a transparent metal oxide material, such as ITO, IZO, indium gallium zinc oxide (IGZO), or the like.

For example, the colors of lights emitted by the plurality of light-emitting devices 30 may be the same or different.

In some examples, the plurality of light-emitting devices 30 includes red light-emitting devices 301, green light-emitting devices 302, and blue light-emitting devices 303. The red light-emitting devices 301 emit red light, the green light-emitting devices 302 emit green light, and the blue light-emitting devices 303 emit blue light.

In some examples, as shown in FIG. 12, the light-emitting device 30 further includes a hole injection layer (HIL) 34, a hole transport layer (HTL) 35, and an electron blocking layer (EBL) 36 that are sequentially stacked on the first electrode 31.

For example, the hole injection layer 34 is used to reduce the potential barrier of hole injection and improve the efficiency of hole injection. The hole injection layer 34 may be a single-layer film made of Hexaazatriphenylenehexacarbonitrile (HATCN), copper phthalocyanine (CuPc) or other materials. Furthermore, the hole injection layer 34 may be formed by performing p-type doping on the hole transport material, for example, performing p-type doping on 4,4′-bis[N-(1-naphthyl)-N-phenylamino]biphenyl (NPB), 2-[4-(dicyanomethylidene)-2,3,5,6-tetrafluorocyclohexa-2,5-dien-1-ylidene]propanedinitri le (F4TCNQ), 4,4′-cyclohexylidenebis[N,N-bis(p-tolyl)aniline](TAPC) or manganese trioxide (MnO3). The concentration of p-type doping is in a range of 0.5% to 10%, inclusive. A thickness of the hole injection layer 34 is in a range of 5 nm to 20 nm. For example, the thickness of the hole injection layer 34 may be 5 nm, 10 nm, 12 nm, 15 nm, or 20 nm.

For example, the hole injection layers 34 of different light-emitting devices 30 are connected to one another to form an one-piece structure. Thus, the manufacturing process of the light emitting device 30 may be simplified.

For example, the hole transport layer 35 is used to transport holes. The material of the hole transport layer 35 may include carbazole-based materials, which results in a high hole mobility. The highest occupied orbital (HOMO) energy level of the material of the hole transport layer 35 needs to be in a range of −5.2 eV to −5.6 eV. The hole transport layer 35 may be formed by evaporation. A thickness of the hole transport layer 35 is in a range of 100 nm to 200 nm, inclusive.

For example, the highest occupied orbital energy level of the material of the hole transport layer 35 may be −5.2 eV, −5.3 eV, −5.4 eV, −5.5 eV or −5.6 eV.

For example, the hole transport layers 35 of different light-emitting devices 30 are connected to one another to form an one-piece structure. Thus, the manufacturing process of the light emitting device 30 may be simplified.

For example, the electron blocking layer 36 may transfer holes to the light-emitting layer 33, and may also block electrons and excitons.

For example, a thickness of the electron blocking layer 36 in the red light-emitting device 301 is in a range of 40 nm to 60 nm, a thickness of the electron blocking layer 36 in the green light-emitting device 302 is in a range of 15 nm to 30 nm, and a thickness of the electron blocking layer 36 in the blue light-emitting device 303 is in a range of 1 nm to 10 nm.

For example, the thickness of the electron blocking layer 36 in the red light-emitting device 301 may be 40 nm, 43 nm, 47 nm, 52 nm or 60 nm; the thickness of the electron blocking layer 36 in the green light-emitting device 302 may be 15 nm, 17 nm, 22 nm, 28 nm or 30 nm; the thickness of the electron blocking layer 36 in the blue light-emitting device 303 may be 1 nm, 3 nm, 5 nm, 7 nm or 10 nm. Thus, it is possible to use the electron blocking layers 36 of different thicknesses to adjust the luminous efficiency of the red light-emitting device 301, the green light-emitting device 302, and the blue light-emitting device 303, so that luminous efficiency of the red light-emitting device 301, the green light-emitting device 302, and the blue light-emitting device 303 tends to be consistent, which is beneficial to improving the display life of the display panel.

For example, the material of the light-emitting layer 33 includes at least a host material and a doping material. For example, the doping material may be a fluorescent material, a delayed fluorescent material or a phosphorescent material.

The host material itself has a poor luminescent property, but has a good film-forming property, and may be mixed with other materials with excellent luminescent property. The guest material (i.e., the doping material) itself has an excellent luminescence property, but has a poor film-forming property. Therefore, in a case where the host material and the guest material doped therein are used as the material of the light-emitting layer, the host material includes molecules in a high excitation energy state, and the molecules in the high excitation energy state may transfer the energy to the guest material, which may change the wavelength of the light emitted by the light-emitting layer, and improve the luminous efficiency of the light-emitting device 30, so that the light-emitting device 30 has an excellent light-emitting property.

For example, a thickness of the light-emitting layer 33 in the red light-emitting device 301 is in a range of 25 nm to 40 nm, inclusive, a thickness of the light-emitting layer 33 in the green light-emitting device 302 is in a range of 25 nm to 40 nm, inclusive, and a thickness of the light-emitting layer 33 in the blue light-emitting device 303 is in a range of 15 nm to 25 nm, inclusive.

In some examples, as shown in FIG. 12, the light-emitting device 30 further includes a hole blocking layer (HBL) 37, an electron transport layer (ETL) 38, and an electron injection layer (EIL) 39 that are sequentially stacked on the light-emitting layer (EML) 33.

For example, the hole blocking layer 37 is used to transport electrons to the light-emitting layer 33 and block holes and excitons. A thickness of the hole blocking layer 37 is in a range from 2 nm to 10 nm.

For example, the thickness of the hole blocking layer 37 may be 2 nm, 4 nm, 6 nm, 8 nm, or 10 nm.

For example, the electron transport layer 38 is used to transport electrons. The material of the electron transport layer 38 includes thiophenes, imidazoles or azine derivatives, and lithium quinolate. The electron transport layer 38 may be formed by blending thiophenes, imidazoles or azine derivatives with lithium quinolate. A mass percentage of lithium quinolate in the material of the electron transport layer 38 is in a range of 30% to 70%, inclusive. A thickness of the electron transport layer 38 is in a range of 20 nm to 40 nm.

For example, the thickness of the electron transport layer 38 may be 20 nm, 24 nm, 32 nm, 38 nm, or 40 nm.

For example, the electron transport layers 38 of different light-emitting devices 30 are connected to one another to form a one-piece structure. Thus, the manufacturing process of the light emitting device 30 may be simplified.

For example, the electron injection layer 39 is used to reduce the potential barrier of electron injection, improve the efficiency of electron injection, and thereby improve the light extraction efficiency of the light-emitting device 30.

For example, a material of the electron injection layer 39 includes lithium fluoride (LiF), lithium quinolin-8-olate (LiQ), ytterbium (Yb), or calcium (Ca). The electron injection layer 39 may be formed by evaporation. A thickness of the electron injection layer 39 is in a range of 0.5 nm to 2 nm.

For example, the thickness of the electron injection layer 39 may be 0.5 nm, 0.7 nm, 1.2 nm, 1.8 nm, or 2 nm.

It will be understood that FIGS. 12, 14, and 16 only illustrate the relative positional relationship between the hole injection layer 34, the hole transport layer 35, the electron blocking layer 36, the light-emitting layer 33, the hole blocking layer 37, the electron transport layer 38, and the electron injection layer 39 in the light-emitting device 30, which does not represent the relative thickness relationship. For the specific thickness, reference will be made to the description in the above examples.

In some embodiments, as shown in FIG. 13, the plurality of second openings 71 include red openings 711 for arranging the red light-emitting devices 301, green openings 712 for arranging the green light-emitting devices 302, and blue openings 713 for arranging the blue light-emitting devices 303. An area of an orthographic projection of the red opening 711 on the backplane is less than or equal to an area of an orthogonal projection of the green opening 712 on the backplane.

For example, a size of the second opening 71 is equal to a light-emitting area of the corresponding red light-emitting device 301 or the green light-emitting device 302 or the blue light-emitting device 303. That is, the light-emitting area of the red light-emitting device 301 is less than or equal to the light-emitting area of the green light-emitting device 302.

In the case where the red light emitted by the plurality of red light-emitting devices 301, the green light emitted by the plurality of green light-emitting devices 302, and the blue light emitted by the plurality of blue light-emitting devices 303 cooperate to synthesize white light, by using the above arrangement, the color purity of the white light synthesized by the plurality of light-emitting devices is high, which is beneficial to reducing the probability of color shift in the display image of the display panel 10, so that it is beneficial to improving the contrast and display effect of the display panel 10.

Moreover, it is possible to use the different light-emitting areas to adjust and coordinate the luminescent life of the red light-emitting devices 301, the green light-emitting devices 302 and the blue light-emitting devices 303, for example, to make the luminescent life of the red light-emitting devices 301, the green light-emitting devices 302 and the blue light-emitting devices 303 is substantially the same, thereby improving the service life of the light-emitting devices 30 and the display panel 10.

In some embodiments, a ratio of the area of the orthographic projection of the blue opening 713 on the backplane 20 to the area of the orthographic projection of the red opening 711 on the backplane 20 is γ, 1.0≤γ≤2.6. Correspondingly, a ratio of a light-emitting area of the blue light-emitting device 303 to a light-emitting area of the red light-emitting device 301 is γ, 1.0≤γ≤2.6.

For example, the ratio of the area of the orthographic projection of the blue opening 713 on the backplane 20 to the area of the orthographic projection of the red opening 711 on the backplane 20 is 2.6, 2.4, 2.3, 2.0, 1.6 or 1.0.

With the above arrangement, the ratio of the light-emitting area of the blue light-emitting device 303 to the light-emitting area of the red light-emitting device 301 may be within an appropriate range, so that the white light synthesized by combining the light emitted by the blue light-emitting device 303, the light emitted by the red light-emitting device 301, and the light emitted by the green light-emitting device 302 has a high purity, and thus the white light emitted by the display panel 10 has a high color purity and the service life of the light-emitting device 30 and the display panel 10 is prolonged to a certain extent.

In some embodiments, a sum of areas of the orthographic projections of all the blue openings 713 in the display region of the display panel 10 on the backplane 20 is less than or equal to 10% of an area of the display region of the display panel 10.

For example, the sum of the areas of the orthographic projections of the plurality of blue openings 713 on the backplane 20 is 10%, 9%, 8%, 7% or 6% of the area of the display region of the display panel 10. In this case, the pixels per inch (PPI) may be greater than or equal to 400. For example, the pixels per inch may be 400, 420, or 600.

Since the luminous efficiency of the light-emitting layer 33 in the green light-emitting device 302 is low, the above arrangement may ameliorate the problem of color shift caused by the difference in luminous efficiency of the blue light-emitting device 303, the red light-emitting device 301 and the green light-emitting device 302; for example, in a case where the display panel needs to display a white image, it is possible to ameliorate a situation that the white color displayed on the display panel may be reddish or bluish, thereby improving the display effect of the display panel.

In some embodiments, a ratio of a sum of the areas of the orthographic projections of all the second openings 71 in the display region on the backplane 20 to the area of the display region of the display panel 10 is in a range of 10% to 70%, inclusive.

For example, the ratio of the sum of the areas of the orthographic projections of the plurality of second openings 71 on the backplane 20 to the area of the display region of the display panel 10 is 10%, 30%, 50%, 60% or 70%.

By setting the range of the sum of the areas of the projections of the plurality of second openings 71 on the backplane, it is possible to limit the sum of the light-emitting areas of the plurality of light-emitting devices 30, so that the sum of the light-emitting areas of the plurality of light-emitting devices 30 is large. Thus, the display brightness of the display panel 10 is increased, and the power consumption of the display panel 10 and the display apparatus 1 is reduced.

The inventors have carried out a test on the brightness and power consumption of the display panel 10 in the above embodiments of the present disclosure. Specifically, the area of the orthographic projection of the red opening 711 on the backplane 20 is set to be 153 μm, the area of the orthographic projection of the green opening 712 on the backplane 20 is set to be 275 μm, and the area of the orthographic projection of the blue opening 712 on the backplane 20 is set to be 275 μm; the area of the orthographic projection of the blue opening 712 on the backplane 20 is 11% of the area of the display region of the display panel 10, and the pixels per inch is 463; the brightness and power consumption of a display panel in an implementation that includes no light extraction layer and light blocking layer is taken as a reference value of 100%, the change of brightness of light with different colors and the change of power consumption of the display panel including the light extraction layer 40 and the light blocking layer 60 are calculated and obtained in Table 1, which is shown below.

For convenience of description, the display panel including no light extraction layer and light shielding layer in an implementation is set as the display panel P1 in the following, and the display panel including a light extraction layer and a light shielding layer in the embodiments of the present disclosure is set as the display panel P2.

The indentation value L in Table 1 represents the distance between the border line of the orthographic projection of the first opening 61 of the light shielding layer 60 on the backplane 20 and the border line of the orthographic projection of the corresponding second opening 71 in the definition layer 70 on the backplane 20. The power consumption in Table 1 is obtained under the condition that the brightness of white light is 500 nits and the color coordinates are (0.31, 0.32).

TABLE 1

| | | Red light-emitting | | Green light-emitting | | Blue light-emitting | | |
|---|---|---|---|---|---|---|---|---|
| Whether | | device and red light | | device and green light | | device and blue light | | |
| including a | | emitted thereby | | emitted thereby | | emitted thereby | | |
| light extraction | | | Color | | Color | | Color | |
| layer and a light | Indentation | Luminous | coordinates | Luminous | coordinates | Luminous | coordinates | Power |
| shielding layer | value L | brightness | CIE (x, y) | brightness | CIE (x, y) | brightness | CIE (x, y) | consumption |
| No | / | 100% | (0.680, 0.320) | 100% | (0.241, 0.722) | 100% | (0.138, 0.043) | 100% |
| Yes | 4 μm | 152% | (0.679, 0.321) | 138% | (0.239, 0.723) | 129% | (0.139, 0.042) | 73.8% |

It can be seen from Table 1, compared with the display panel P1, the brightness of the light emitted by the display panel P2 provided by the embodiments of the present disclosure is greatly improved. Specifically, in a case where the color coordinates of the light emitted by the display panel P1 are substantially the same as the color coordinates of the light emitted by the display panel P2, compared with the display panel P1, the brightness of the red light emitted by the display panel P2 is increased by approximately 52%, the brightness of the green light is increased by approximately 38%, and the brightness of the blue light is increased by approximately 29%. After the white balance is adjusted, in a case where the color coordinates are (0.31, 0.32) and the luminous brightness is 500 nits, compared with the display panel P1, the power consumption of the display panel P2 is reduced by 26.2% (26.2%=1-73.8%). Thus, by using the display panel provided by the embodiments of the present disclosure for display, it may be possible to greatly reduce the power consumption.

The inventors have also tested the luminescence situations of various display panels P2 with different indentation values L. Specifically, in each display panel P2, the area of the orthographic projection of the red opening 711 on the backplane 20 is set to be 153 μm, the area of the orthographic projection of the green opening 712 on the backplane 20 is set to be 275 μm, and the area of the orthographic projection of the blue opening 713 on the backplane is set to be 275 μm; the area of the orthographic projection of the blue opening 713 on the backplane 20 is 11% of the area of the display region of the display panel 10, and the pixels per inch is 463. The power consumption of display panel P1 is taken as a reference value of 100%, the power consumption, reflectivity and side view brightness loss rate of the display panel P2 are obtained, as shown in Table 2.

In Table 2, the reflectivity of the display panel P1 and the display panel P2 are both measured under a case that the incident wavelength is 530 nm. The side view brightness loss rate refers to a ratio of a difference between the brightness value of the display panel at the front viewing angle and the brightness value of the display panel at the side viewing angle of 30°, to the brightness value of the display panel at the front viewing angle.

TABLE 2

| Whether including | | | | Side view |
|---|---|---|---|---|
| a light extraction | | | Reflec- | brightness |
| layer and a light | Indentation | Power | tivity | loss rate |
| shielding layer | value L (μm) | consumption | (530 nm) | (30°) |
| No | / | 100% | 6.0% | 32% |
| Yes | 2 | 73.8% | 5.7% | 45% |
| Yes | 3 | 73.8% | 6.0% | 39% |
| Yes | 4 | 73.8% | 6.5% | 35% |

It can be seen from Table 2 that in a case where the indentation value L is 2 μm, 3 μm, and 4 μm, the power consumption of the display panel P2 remains unchanged basically, all of which is reduced by about 26.2%, and the brightness of the display panel P2 also remains unchanged basically (not shown in Table 2). Therefore, the magnitude of the indentation value L basically does not affect the brightness and power consumption of the display panel P2. As the indentation value L decreases, the reflectivity of the display panel gradually decreases, and the anti-reflective capability of the display panel becomes stronger. Therefore, setting a small indentation value L may improve the anti-reflective capability of the display panel.

It can be seen from Table 2, compared with the side view brightness loss rate of display panel P1 of 32%, the side view brightness loss rates of display panel P2 provided by embodiments of the present disclosure are 35%, 39%, and 45%, which are all greater than 32%. It can be seen that compared with the display panel P1, the side view brightness loss rate of the display panel P2 is improved, so that the display panel has a good privacy protection function. Moreover, as the indentation value L decreases, the side view brightness loss rate of the display panel P2 gradually increases. Thus, the less the brightness of the display image of the display panel P2 viewed by the user in the side viewing angle, and the better the privacy protection effect of the display panel P2. Especially in a case where the indentation value L is 2 μm, the side view brightness loss rate of the display panel P2 reaches about 45%, so that the display panel has a good privacy protection effect.

The inventors also have explored the effect of aperture ratio (the aperture ratio here is the ratio of the area of the orthographic projection of the red opening, green opening or blue opening on the backplane to the area of the display area of the display panel) of the display panel on the power consumption, brightness and service life of the display panel, and the power consumption, brightness and service time of the display panel are obtained by setting different aperture ratios, and Table 3 is obtained.

In Table 3, R aperture ratio represents the aperture ratio of the red opening, G aperture ratio represents the aperture ratio of the green opening, B aperture ratio represents the aperture ratio of the blue openings, and R/G/B represents that a ratio of the aperture ratio of the red opening to the aperture ratio of the green opening and the aperture ratio of the blue opening. The power consumption of the display panel is measured under the conditions that the color coordinates are (0.31, 0.32) and the luminous brightness is 500 nits. Total aperture ratio represents a ratio of a sum of areas of the orthographic projections of the plurality of second openings (the plurality of red openings, the plurality of green openings, and the plurality of blue openings) on the backplane to the area of the display region of the display panel. Embodiments 1 to 8 show display panels with different aperture ratios provided by the present disclosure, and Reference Examples 1 to 2 are display panels including no light extraction layer and light shielding layer.

It can be seen from Table 3 that the display panel in Reference Example 1 is not provided with a light extraction layer and a light shielding layer therein, and the display panel in Embodiment 1 is provided with a light extraction layer and a light shielding layer therein; for the display panel in Reference Example 1 and the display panel in Embodiment 1, the total aperture ratios are the same, and the power consumption is the same. The brightness of the display panel in Embodiment 1 is 680 nits, and the brightness of the display panel in Reference Example 1 is 500 nits. Compared with the brightness of the display panel in Reference Example 1, the brightness of the display panel in Embodiment 1 is improved by about 36%. Therefore, by providing the light extraction layer and the light shielding layer in the display panel provided by the embodiments of the present disclosure, the display brightness of the display panel is effectively improved without changing the aperture ratio and power consumption.

TABLE 3

| Whether including a | | | | | | | Power | | |
|---|---|---|---|---|---|---|---|---|---|
| light extraction layer | | R | G | B | | Total | consumption | | Service |
| and a light shielding | | aperture | aperture | aperture | | aperture | of the display | Brightness | life |
| layer | | ratio | ratio | ratio | R/G/B | ratio | panel | (nits) | (hrs) |
| Reference | No | 6.1% | 7.4% | 11.0% | 1:1.2:1.8 | 24.5% | 100% | 500 | 100% |
| example 1 | | | | | | | | | |
| Reference | No | 4.5% | 5.5% | 8.0% | 1:1.2:1.8 | 18% | 100% | 365 | 101% |
| example 2 | | | | | | | | | |
| Embodiment | Yes | 6.1% | 7.4% | 11.0% | 1:1.2:1.8 | 24.5% | 100% | 680 | 103% |
| 1 | | | | | | | | | |
| Embodiment | Yes | 4.1% | 5.4% | 8.5% | 1:1.3:2.1 | 18% | 100% | 500 | 100% |
| 2 | | | | | | | | | |
| Embodiment | Yes | 3.6% | 4.7% | 9.7% | 1:1.3:2.7 | 18% | 100% | 480 | 84% |
| 3 | | | | | | | | | |
| Embodiment | Yes | 4.7% | 6.2% | 7.1% | 1:1.3:1.5 | 18% | 100% | 495 | 120% |
| 4 | | | | | | | | | |
| Embodiment | Yes | 5% | 6.5% | 6.5% | 1:1.3:1.3 | 18% | 100% | 485 | 145% |
| 5 | | | | | | | | | |
| Embodiment | Yes | 3.8% | 4.9% | 9.3% | 1:1.3:2.5 | 18% | 100% | 485 | 90% |
| 6 | | | | | | | | | |
| Embodiment | Yes | 4.3% | 4.7% | 9.0% | 1:1.1:2.1 | 18% | 100% | 488 | 90% |
| 7 | | | | | | | | | |
| Embodiment | Yes | 3.7% | 6.6% | 7.7% | 1:1.8:2.1 | 18% | 100% | 500 | 135% |
| 8 | | | | | | | | | |

It can be seen from Table 3 that, compared with Reference Example 2, the total aperture ratio of the display panel in Embodiment 2 is reduced by 6.5% (6.5%=24.5%-18%), and for the display panel in Reference Example 2 and the display panel in Embodiment 2, the luminous brightness, power consumption and service life are all respectively the same. Therefore, without losing the power consumption and service life of the display panel, the display panel provided by the embodiments of the present disclosure can greatly reduce the total aperture ratio of the display panel, so that the saved space may be used to make the display panel have a high resolution.

It can be seen from Table 3, a ratio of R aperture ratio to G aperture ratio of the display panel in Embodiment 2, a ratio of R aperture ratio to G aperture ratio of the display panel in Embodiment 4, and a ratio of R aperture ratio to G aperture ratio of the display panel in Embodiment 4 are set to equal, and a ratio of 2.1 of B aperture ratio to R aperture ratio in Embodiment 2 is set to be greater than a ratio of 1.5 of B aperture ratio to R aperture ratio of the display panel in Embodiment 4, and is greater than a ratio of 1.3 of B aperture ratio to R aperture ratio of the display panel in Embodiment 5, and then the brightness and service life of the display panel are tested. Compared with Embodiment 2, the brightness of the display panel in Embodiment 4 and Embodiment 5 is reduced slightly, and the service life of the display panel is significantly improved. In Embodiment 3, a ratio of B aperture ratio to R aperture ratio of the display panel is 2.7, which is greater than 2.6, the service life of the display panel drops to less than 90%, and the brightness of the display panel is also reduced. Therefore, in the display panel provided in the embodiments of the present disclosure, the ratio of the area of the orthographic projection of the blue opening on the backplane to the area of the orthographic projection of the red opening on the backplane is less than or equal to 2.6, which may improve the display brightness of the display panel, and prolong the display life.

It can be seen from Table 3, compared with Embodiment 2, R aperture ratio of the display panel in Embodiment 7 is large, and R aperture ratio and G aperture ratio are close to each other in Embodiment 7, and the service life of the display panel in Embodiment 7 (90%) is reduced compared with that in Embodiment 2 (100%), but the amount of the reduction is small and within the acceptable range. Thus, it may be predicted that if the aperture ratio of R in the display panel continues to be increased, the service life of the display panel will continue to decrease. Therefore, in the embodiments of the present disclosure, the area of the orthographic projection of the red opening on the backplane is set to be less than or equal to the area of the orthogonal projection of the green opening on the backplane, which may ensure that the display panel has a long service life and a high display brightness.

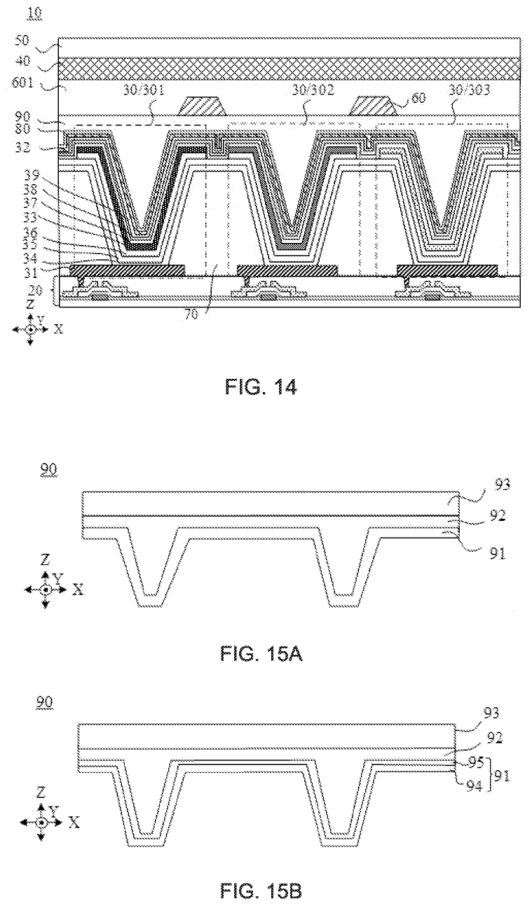

In some embodiments, as shown in FIG. 14, the display panel 10 further includes: an optical covering layer 80 located between the plurality of light-emitting devices 30 and the light extraction layer 40, and an encapsulation layer 90 located between the optical covering layer 80 and the light extraction layer 40 and contact with the optical covering layer 80. The encapsulation layer 90 may encapsulate and protect the light-emitting devices 30.

For example, a material of the optical covering layer 80 may be a light-transmitting material. Of course, the encapsulation layer 90 may be transparent. Thus, it is possible to ensure that the light emitted by the light-emitting device 30 is able to pass through the encapsulation layer 90 and the optical covering layer 90 and to be incident on the light shielding layer 60.

For example, a difference between refractive index of the optical covering layer 80 and refractive index of the encapsulation layer 90 is greater than or equal to 0.1.

For example, the difference between the refractive index of the optical covering layer 80 and the refractive index of the encapsulation layer 90 may be 0.1, 0.15, 0.2, 0.5, or 0.6.

In a process that the light emitted by the light-emitting device 30 is incident on the encapsulating layer 90 through the optical covering layer 80, since the refractive index of the optical covering layer 80 is greater than the refractive index of the encapsulation layer 90, the encapsulation layer 90 has a certain converging effect on the light; thus, the loss of the light emitted by the light-emitting device may be reduced, and the luminous efficiency of the light-emitting device 30 may be improved, so that the display brightness of the display panel may be further improved to increase the display life. Moreover, in a case where the display panel is used in a privacy-preventing scene, the viewing angle of the light emitted by each light-emitting device 30 may be controlled within a relatively small viewing angle range by adjusting the difference range between the refractive index of the optical covering layer 80 and the refractive index of the encapsulation layer 90, so that the privacy protection effect of the display panel may be enhanced to a certain extent.

For example, the optical covering layer 90 may include at least two covering sub-layers stacked in sequence. The refractive index of two adjacent covering sub-layers is different. Thus, the reflectivity of the display panel 10 to external light may be reduced, thereby improving the anti-reflection capability of the display panel 10.

In some embodiments, as shown in FIG. 15A, the encapsulation layer 90 includes at least three encapsulation sub-layers that are stacked. Refractive indexes of at least two encapsulation sub-layers of the at least three encapsulation sub-layers are greater than or equal to 1.65.

In some examples, a material of the encapsulation sub-layer includes an organic material or inorganic material. The materials of the three encapsulation sub-layers may be an organic material, inorganic material, and organic material in order. Alternatively, as shown in FIG. 15A, the materials of the three encapsulation sub-layers may be an inorganic material, organic material, and inorganic material in order.

The encapsulation sub-layer made of the inorganic material may be formed by chemical vapor deposition (CVD), and the encapsulation sub-layer made of the organic material may be formed by ink jet printing (IJP).

The inorganic material may be a silicon-containing inorganic material, and the silicon-containing inorganic material may be at least one of silicon dioxide (SiO₂), silicon nitride (SiNx), and silicon oxynitride (SiON). The organic material may be an acrylic-based polymer, a silicon-based polymer, or other polymers. The encapsulation sub-layer made of the inorganic material has good moisture and oxygen barrier property, which may prevent external moisture and oxygen from affecting the organic material (e.g. the material of the light-emitting layer) in the light-emitting device. The encapsulation sub-layer made of the organic material may absorb and disperse the stress between layers well, thereby avoiding the reduction of the moisture and oxygen barrier property caused by the crack of the encapsulation sub-layer made of the dense inorganic material. Therefore, the encapsulation layer 90 may protect the light-emitting devices 30 from the intrusion of moisture and oxygen, which increases the service life of the light-emitting device, and thereby increasing the service life of the display panel and the display apparatus.

For example, as shown in FIG. 15A, in a case where the at least three encapsulation sub-layers included in the encapsulation layer 90 include a first encapsulation sub-layer 91, a second encapsulation sub-layer 92 and a third encapsulation sub-layer 93, the material of the second encapsulation sub-layer 92 is an organic material, the material of the first encapsulation sub-layer 91 is an inorganic material, and an orthographic projection of the second encapsulation sub-layer 92 on the backplane 20 is located within an orthographic projection of the first encapsulation sub-layer 91 on the backplane 20.

For example, the refractive index of the first encapsulation sub-layer 91 and the refractive index of the second encapsulation sub-layer 92 are both greater than 1.65.

For another example, the refractive index of the first encapsulation sub-layer 91, the refractive index of the second encapsulation sub-layer 92 and the third encapsulation sub-layer 93 are all greater than 1.65.

With the above arrangement, the encapsulation layer 90 may be used to adjust the emission angle of the light emitted by the light-emitting device 30, and most of the light emitted by the light-emitting device 30 may be emitted through the encapsulation layer 90.

For example, as shown in FIG. 15B, the first encapsulation sub-layer 91 is in contact with the optical covering layer 80, and the first encapsulation sub-layer 91 includes a fourth encapsulation sub-layer 94 and a fifth encapsulation sub-layer 95 that are stacked.

For example, a material of the fourth encapsulation sub-layer 94 is different from the material of the fifth encapsulation sub-layer 95.

For another example, the material of the fourth encapsulation sub-layer 94 is the same as the material of the fifth encapsulation sub-layer 95.

For example, the refractive index of the fourth encapsulation sub-layer 94 is different from the refractive index of the fifth encapsulation sub-layer 95.

For example, the refractive index of the fourth encapsulation sub-layer 94 is less than the refractive index of the fifth encapsulation sub-layer 95, or the refractive index of the fourth encapsulation sub-layer 94 is greater than the refractive index of the fifth encapsulation sub-layer 95.

With the above arrangement, the fourth encapsulation sub-layer 94 and the fifth encapsulation sub-layer 95 with different refractive indexes may be used to adjust the light emitted by the light-emitting device 30, so that most of the light emitted by the light-emitting device 30 emits in a direction perpendicular to the display panel, which is beneficial to improving the light extraction efficiency of the light-emitting device 30, and achieving the privacy protection function of the display panel.

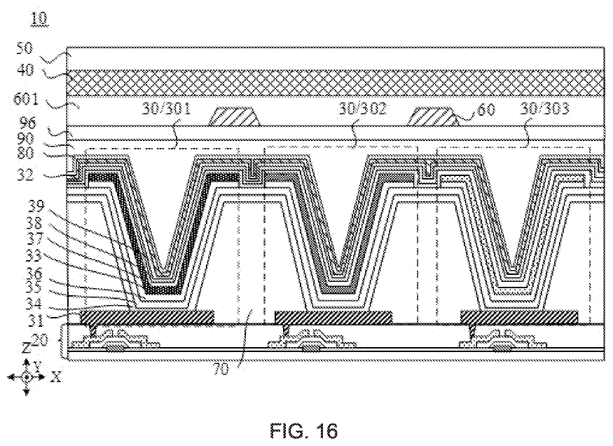

In some embodiments, as shown in FIG. 16, the display panel 10 further includes a touch function layer 96 located between the encapsulation layer 90 and the light extraction layer 40.

For example, the touch function layer 96 may be located between the planarization layer 601 and the encapsulation layer 90.

It will be understood that the structure of the touch function layer 96 may vary, and may be set according to the actual situation, and is not limited in the present disclosure.

For example, the touch function layer 96 may be of a flexible single-layer on cell (FSLOC) structure or a flexible multi-layer on cell (FMLOC) structure. The FMLOC structure is made of forming a metal grid electrode layer on an encapsulation driving backplane of the display panel to perform touch control without providing a touch screen panel (TSP) outside, which may reduce the thickness of the display panel, improve the yield, and reduce the cost.

For example, the touch functional layer may include a plurality of touch driving electrodes and a plurality of touch sensing electrodes. The touch driving electrode may emit a low voltage and high frequency signal, and the touch sensing electrode may receive the low voltage and high frequency signal, so that a stable capacitance is formed between the two. The touch of the user will cause different capacitance changes between the touch driving electrode and the touch sensing electrode, thereby achieving corresponding touch operations.

Therefore, the touch function layer 96 may be used to enable the display panel 10 to implement touch operations. Moreover, the anti-reflective layer 50 may be used to reduce the light incident on the touch functional layer 96, thereby avoiding the impact on the operation state of the touch functional layer 96.

Beneficial effects that may be achieved by the display device 1000 provided in some embodiments of the present disclosure are the same as the beneficial effects that can be achieved by the display panel 200 provided in some embodiments described above, which will not be repeated here.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display panel, comprising:
a backplane;
a plurality of light-emitting devices located on the backplane, wherein a light-emitting device includes a first electrode and a second electrode arranged oppositely, the first electrode is closer to the backplane than the second electrode;
a light extraction layer located on a light exit side of the plurality of light-emitting devices, wherein the light extraction layer is configured to allow circularly polarized light of a first rotation direction to pass through and reflect circularly polarized light of a second rotation, the first rotation direction is different from the second rotation direction; and
an anti-reflection layer located on the light extraction layer, wherein the anti-reflection layer is configured to allow the circularly polarized light of the first rotation direction to pass through.

2. The display panel according to claim 1, wherein a transmittance of the light extraction layer to light emitted by the light-emitting device is greater than or equal to 35%, and/or a reflectivity of the light extraction layer to the light emitted by the light-emitting device is greater than or equal to 35%.

3. The display panel according to claim 1, wherein a material of the extraction layer includes at least one type of cholesteric liquid crystals;
in a case where the material of the light extraction layer includes at least two types of cholesteric liquid crystals, helical pitches of the at least two types of cholesteric liquid crystals are not equal.

4. The display panel according to claim 3, wherein in the case where the material of the light extraction layer includes at least two types of cholesteric liquid crystals,
the light extraction layer includes at least two light extraction sub-layers stacked in sequence; the at least two light extraction sub-layers include a first light extraction layer and a second light extraction layer, and a helical pitch of cholesteric liquid crystals in the first light extraction layer and a helical pitch of cholesteric liquid crystals in the second light extraction layer are not equal; or in the light extraction layer, helical pitches of cholesteric liquid crystals corresponding to light-emitting devices 30 with different light-emitting colors are not equal.

5. The display panel according to claim 3, wherein in the case where the material of the light extraction layer includes at least two types of cholesteric liquid crystals,
the at least two types of cholesteric liquid crystals include first liquid crystals and second liquid crystals; the first liquid crystals are evenly distributed in the light extraction layer, the second liquid crystals are evenly distributed in the light extraction layer, and a distribution density of the first liquid crystals in the light extraction layer is substantially equal to a distribution density of the second liquid crystals in the light extraction layer.

6. (canceled)

7. The display panel according to claim 1, the anti-reflection layer includes at least a ¼ wave plate and a polarizing layer; the ¼ wave plate is located between the polarizing layer and the light extraction layer; a transmittance of the polarizing layer to visible light is greater than or equal to 40%; or
the anti-reflection layer includes at least a ¼ wave plate and a polarizing layer; the ¼ wave plate is located between the polarizing layer and the light extraction layer; a transmittance of the polarizing layer to visible light is greater than or equal to 40%; the anti-reflection layer further includes a light absorption layer; the light absorption layer is stacked on the ¼ wave plate or the polarizing layer, and is used to absorb light with a wavelength in a range below 450 nm.

8. (canceled)

9. The display panel according to claim 1, further comprising: a definition layer located between the backplane and the light extraction layer, the definition layer having a plurality of second openings;
wherein the plurality of light-emitting devices include red light-emitting devices, a green light-emitting devices and blue light-emitting devices;
the plurality of second openings include red openings for arranging the red light-emitting devices, green openings for arranging the green light-emitting devices, and blue openings for arranging the blue light-emitting devices; and
an area of an orthographic projection of a red opening on the backplane is less than or equal to an area of an orthogonal projection of a green opening on the backplane.

10. The display panel according to claim 9, wherein a ratio of an area of an orthographic projection of a blue opening on the backplane to the area of the orthographic projection of the red opening on the backplane is γ, where 1.0≤γ≤2.6; and/or
a sum of areas of orthographic projections of all the blue openings in a display region of the display panel on the backplane is less than or equal to 10% of an area of the display region of the display panel.

11. (canceled)

12. The display panel according to claim 9, wherein a ratio of a sum of areas of orthographic projections of all the second openings in a display region of the display panel on the backplane to an area of the display region is in a range of 10% to 70%, inclusive; and/or
an included angle between a side wall of a second opening and a plane where the backplane is located is less than or equal to 35°.

13. (canceled)

14. The display panel according to claim 1, further comprising a light shielding layer disposed between the plurality of light-emitting devices and the light extraction layer, the light shielding layer having a plurality of first openings; wherein
an orthogonal projection of the light-emitting device on the backplane and an orthogonal projection of a first opening on the backplane have an overlapping region therebetween.

15. The display panel according to claim 14, wherein the display panel has a first region and a second region; wherein
an included angle between a side wall of at least one first opening in the first region and a plane where the backplane is located is not equal to an included angle between a side wall of at least one first opening in the second region and the plane where the backplane is located.

16. The display panel according to claim 14, further comprising a definition layer located between the backplane and the light shielding layer; the definition layer having a plurality of second openings; wherein
a second opening is arranged directly opposite to a first opening in a direction perpendicular to a plane where the backplane is located.

17. The display panel according to claim 16, wherein the display panel has a third region and a fourth region; wherein
an included angle between a side wall of at least one second opening in the third region and the plane where the backplane is located is not equal to an included angle between a side wall of at least one second opening in the fourth region and the plane where the backplane is located; and/or
an orthographic projection of the second opening on the backplane is within an orthographic projection of the first opening directly opposite to the second opening on the backplane.

18. (canceled)

19. The display panel according to claim 16, wherein an included angle between a side wall of the first opening and the plane where the backplane is located is greater than an included angle between a side wall of the second opening and the plane where the backplane is located; or
an included angle between a side wall of the first opening and the plane where the backplane is located is less than an included angle between a side wall of the second opening and the plane where the backplane is located.

20. (canceled)

21. The display panel according to claim 16, wherein a material of the definition layer includes a light absorbing material, and/or a material of the light shielding layer includes a light absorbing material; absorbance of the light shielding material is greater than or equal to 0.5; and/or
a maximum distance between a border line of an orthographic projection of the second opening on the backplane and a border line of the orthographic projection of the first opening directly opposite to the second opening on the backplane is less than or equal to ⅓ of a maximum size of the orthographic projection of the second opening on the backplane.

22. (canceled)

23. The display panel according to claim 1, further comprising:
an optical covering layer located between the plurality of light emitting devices and the light extraction layer; and
an encapsulation layer located between the optical covering layer and the light extraction layer and in contact with the optical covering layer;
wherein a difference between refractive index of the optical covering layer and refractive index of the encapsulation layer is greater than or equal to 0.1.

24. The display panel according to claim 23, wherein the encapsulation layer includes at least three encapsulation sub-layers; and
refractive indexes of at least two encapsulation sub-layers of the at least three encapsulation sub-layers are greater than or equal to 1.65.

25. The display panel according to claim 24, wherein the at least three encapsulation sub-layers include a first encapsulation sub-layer, a second encapsulation sub-layer and a third encapsulation sub-layer; the first encapsulation sub-layer is in contact with the optical covering layer; a material of the first encapsulation sub-layer is an inorganic material, a material of the second encapsulation sub-layer is an organic material, and a material of the third encapsulation sub-layer is an inorganic material; wherein
the first encapsulation sub-layer includes a fourth encapsulation sub-layer and a fifth encapsulation sub-layer that are stacked; or
the first encapsulation sub-layer includes a fourth encapsulation sub-layer and a fifth encapsulation sub-layer that are stacked, and a refractive index of the fourth encapsulation sub-layer is less than a refractive index of the fifth encapsulation sub-layer.

26. (canceled)

27. The display panel according to claim 23, further comprising a touch function layer located between the encapsulation layer and the light extraction layer.

28. A display apparatus, comprising the display panel according to claim 1.
